(19) United States
(12) Patent Application Publication
(10) Pub. No.: US 2025/0109224 A1
(43) Pub. Date: Apr. 3, 2025

(54) BLENDS OF CONJUGATED AND ADHESIVE POLYMERS FOR STICKY ORGANIC THIN-FILM TRANSISTORS

(71) Applicants: Purdue Research Foundation, West Lafayette, IN (US); The Penn State Research Foundation, University Park, PA (US)

(72) Inventors: Jonathan WILKER, West Lafayett, IN (US); Enrique Daniel GOMEZ, University Park, PA (US); Clayton R. WESTERMAN, Leo, IN (US); Sang Ha YOO, Gilbert, AZ (US); James G. SUTJIANTO, Midland, MI (US)

(21) Appl. No.: 18/900,174

(22) Filed: Sep. 27, 2024

Related U.S. Application Data
(60) Provisional application No. 63/586,316, filed on Sep. 28, 2023.

(51) Int. Cl. C08F 212/14; C08F 212/08; C08G 61/12; H10K 10/46

(52) U.S. Cl. CPC C08F 212/24; C08F 212/08; C08G 61/124; C08G 61/126; H10K 10/462

(57) ABSTRACT

Blended polymers that exhibit both conductive and adhesive properties are provided. OTFTs comprising such polymers are also provided, as are methods of manufacturing the same.

### PRIORITY

The present application is related to and claims the priority benefit of U.S. Provisional Patent Application No. 63/586,316, filed Sep. 28, 2023, the content of which is hereby expressly incorporated by reference in its entirety into this disclosure.

### GOVERNMENT FUNDING

This invention was made with government support under N00014-19-1-2342 awarded by the U.S. Office of Naval Research/United States Navy, and under DMR1921854 and DGE-1255832, both awarded by the National Science Foundation. The government has certain rights in the invention.

### BACKGROUND

Organic thin-film transistors (OTFTs) have garnered significant attention because of their large area compatibility, potential solution processability, and stretchability. Previous efforts have fabricated OTFTs with field-effect carrier charge mobilities greater than 1 cm² V⁻¹s⁻¹, which rivals commercially available hydrogenated amorphous silicon transistors.

Recently, it has been shown that blend systems can be utilized to achieve high-performance OTFTs. Blends can be formulated to serve as the gate insulator layer or the semiconductor active layer. To serve as the active layer, blends of conjugated polymers, conjugated polymers with insulating polymers, and conjugated polymers with conjugated small molecules have been demonstrated.

Conjugated polymers can be amenable to blending, in particular when they are semicrystalline. Crystallization of the polymer can create a pure phase where charge conduction can occur unimpeded by secondary components. The fibril-like crystallization motif of most conjugated polymers can promote percolation of charge conducting pathways. The amorphous phase in conjugated polymers can uptake various other components without substantially disrupting conduction through crystalline domains. In addition, many of these polymers will often crystallize near an interface, thereby excluding other components and creating a conducting channel in bottom-gate, bottom-contact transistors.

One possible class of materials to blend with conjugated polymers is adhesives. Strong adhesion can be desirable to prevent delamination, especially under humid conditions, and to allow for 3D integration. What is needed is an adhesive-blended OTFT to help facilitate conduction and also adhesion to a substrate.

### TECHNICAL FIELD

The present disclosure relates to blended polymers that exhibit both conductive and adheisve properties. Organic thin-film transistors (OTFTs) comprising such polymers are also provided, as well as methods for manufacturing the same.

### SUMMARY

A polymer (e.g. a polymer blend) comprising a poly(vinyl catechol-styrene) (PCS) and at least one conjugated polymer, the conjugated polymer comprising at least one poly(alkyl-thiophene) derivative or at least one high-performance donor-acceptor polymer is provided. The poly(alkyl-thiophene) derivative of the polymer can comprise, for example, poly(3-hexylthiophene-2,5-diyl) (P3HT) or poly[2,5-bis(3-tetradecylthiophen-2-yl) thieno[3,2-b]thiophene] (PBTTT). The high-performance donor-acceptor polymer can comprise, for example, poly[2,5-(2-octyldodecyl)-3,6-diketopyrrolopyrrole-alt-5,5-(2,5-di(thien-2-yl) thieno[3,2-b]thiophene)] (PDPP). In certain embodiments, the poly(alkyl-thiophene) derivative comprises about 20 weight percentage (wt. %) to about 99 wt. % of the polymer. In certain embodiments of the polymer, the poly(alkyl-thiophene) derivative comprises P3HT and is present in at or about 10-25 wt. % of the polymer. In certain embodiments of the polymer, the high-performance donor-acceptor polymer comprises PDPP and is present in at or about 15-65 wt. % of the polymer. In certain embodiments of the polymer, the high-performance donor-acceptor polymer comprises PDPP and is present in at or about 60 wt. % of the polymer.

The polymer can exhibit both semiconductive and adhesive properties. The polymer can exhibit an adhesive strength of about 0.05 MPa to about 4.30 MPa (such as, 0.05 MPA to about 4.30 MPa, about 0.05 MPa to 4.30 MPa, or 0.05 MPa to 4.30 MPa).

Organic thin-film transistors (OTFTs) are also provided. In certain embodiments, an OTFT comprises a semiconductor active layer comprising any of the polymers (e.g., polymer blends) hereof, at least two electrodes in conductive communication with the active layer, an insulating layer, and a lowermost substrate comprising a gate. In certain embodiments, the semiconductor active layer comprises a polymer blend comprising PCS and at least one conjugated polymer, the conjugated polymer comprising at least one poly(alkyl-thiophene) derivative or at least one high-performance donor-acceptor polymer. The semiconductive active layer can be cast over the at least two electrodes, the insulating layer, and the substrate.

The substrate of the OTFT can comprise heavily doped p-type silicon. The insulating layer can be a dielectric layer. The insulating layer can comprise 300 nm silicon dioxide. In certain embodiments, the silicon dioxide is thermally grown. In certain embodiments, at least one of the electrodes is a drain and at least one of the electrodes is a source. In certain embodiments, at least two of the at least two electrodes are arranged separately from each other. Both the electron source and the electron drain can comprise gold, for example.

The active layer can exhibit an adhesive strength of about 0.05 MPa to about 4.30 MPa (such as 0.05 MPa to about 4.30 MPa, about 0.05 MPa to 4.30 MPa, or 0.05 MPa to 4.30 MPa).

In certain embodiments, the OTFT comprises a bottom gate, bottom contact configuration.

Methods of preparing an OTFT hereof are also provided. In certain embodiments, a method of preparing an OTFT comprises evaporating and patterning two or more electrodes onto a substrate; depositing a polymer blend in solution onto an insulating layer positioned over the substrate or onto the substrate, and processing the deposited polymer blend solution. The polymer blend, for example, can comprise PCS and at least one conjugated polymer. The conjugated polymer can comprise at least one poly(alkyl-thiophene) derivative or at least one high-performance donor-acceptor polymer. The resulting OTFT can comprise a semiconductor active layer comprising the polymer blend, the two or more electrodes are in conductive communication with the semiconductive active layer, and at least a portion of the substrate comprises a gate.

### BRIEF DESCRIPTION OF THE DRAWINGS

The disclosed embodiments and other features, advantages, and disclosures contained herein, and the matter of attaining them, will become apparent and the present disclosure will be better understood by reference to the following description of various exemplary embodiments of the present disclosure taken in conjunction with the accompanying drawings.

FIG. 1 shows the chemical structures of polymers and a schematic of an Organic Thin-Film Transistor (OTFT) device architecture hereof.

FIG. 2(A) shows transfer curves of devices with poly[2,5-bis(3-tetradecylthiophen-2-yl) thieno[3,2-b]thiophene] (PBTTT) as the active layer and PBTTT/poly(vinyl catechol-styrene) (PCS) blend as the active layer with 60 wt. % PBTTT.

FIG. 2(B) shows the saturation mobility of devices comprising PBTTT/PCS blends as the active layer. Width and length of transistor channels were 220 μm and 320 μm, respectively. Error bars denote the standard deviation from measuring 10 devices per composition.

FIG. 2(C) shows a graph of adhesion strength as a function of weight percent of PBTTT in the blended films.

FIG. 2(D) is an image of bonded 60 wt. % poly[2,5-(2-octyldodecyl)-3,6-diketopyrrolopyrrole-alt-5,5-(2,5-di(thien-2-yl) thieno[3,2-b]thiophene)] (PDPP) films in between two silicon wafers holding a 156.3 g cellphone.

FIG. 3 shows transfer curves of devices with (A) a PBTTT/PCS blend as the active layer with 80 wt. % PBTTT, (B) a PBTTT/PCS blend as the active layer with 40 wt. % PBTTT, and (C) a PBTTT/PCS blend as the active layer with 20 wt. % PBTTT. Width and length of transistor channels were 220 μm and 320 μm, respectively.

FIG. 4 shows transfer curves of devices with (A) P3HT as the active layer, (B) a poly(3-hexylthiophene-2,5-diyl) (P3HT)/PCS blend as the active layer with 75 wt. % P3HT, (C) a P3HT/PCS blend as the active layer with 50 wt. % P3HT, and (D) a P3HT/PCS blend as the active layer with 25 wt. % P3HT. Width and length of transistor channels were 220 μm and 320 μm, respectively.

FIG. 5 shows transfer curves of devices with (A) PDPP as the active layer, (B) a PDPP/PCS blend as the active layer with 80 wt. % PDPP, (C) a PDPP/PCS blend as the active layer with 60 wt. % PDPP, (D) a PDPP/PCS blend as the active layer with 40 wt. % PDPP, and (E) a PDPP/PCS blend as the active layer with 20 wt. % PDPP. Width and length of transistor channels were 220 μm and 320 μm, respectively.

FIG. 6 shows output curves of devices with (A) PBTTT as the active layer, (B) a PBTTT/PCS blend as the active layer with 80 wt. % PBTTT, (C) a PBTTT/PCS blend as the active layer with 60 wt. % PBTTT, (D) a PBTTT/PCS blend as the active layer with 40 wt. % PBTTT, and (E) a PBTTT/PCS blend as the active layer with 20 wt. % PBTTT.

FIG. 7 shows output curves of devices with (A) P3HT as the active layer, (B) a P3HT/PCS blend as the active layer with 75 wt. % P3HT, (C) a P3HT/PCS blend as the active layer with 50 wt. % P3HT, and (D) a P3HT/PCS blend as the active layer with 25 wt. % P3HT.

FIG. 8 shows output curves of devices with (A) PDPP as the active layer, (B) a PDPP/PCS blend as the active layer with 80 wt. % PDPP, (C) a PDPP/PCS blend as the active layer with 60 wt. % PDPP, (D) a PDPP/PCS blend as the active layer with 40 wt. % PDPP, and (E) a PDPP/PCS blend as the active layer with 20 wt. % PDPP.

FIG. 9 shows transfer curves of a transistor with PCS as the active layer. Insulative behavior was observed. The width and length of the transistor channels were 220 μm and 320 μm respectively.

FIG. 10 shows mobility curves of devices with (A) PBTTT as the active layer, (B) a PBTTT/PCS blend as the active layer with 80 wt. % PBTTT, (C) a PBTTT/PCS blend as the active layer with 60 wt. % PBTTT, (D) a PBTTT/PCS blend as the active layer with 40 wt. % PBTTT, and (E) a PBTTT/PCS blend as the active layer with 20 wt. % PBTTT.

FIGS. 11(A)-(D) show mobility curves of devices with (A) P3HT as the active layer, (B) a P3HT/PCS blend as the active layer with 75 wt. % P3HT, (C) a P3HT/PCS blend as the active layer with 50 wt. % P3HT, and (D) a P3HT/PCS blend as the active layer with 25 wt. % P3HT.

FIG. 11(E) shows data related to the saturation mobility of devices with P3HT/PCS blends as the active layer. Error bars denote the standard deviation from measuring 10 devices per blend.

FIGS. 12(A)-(E) show mobility curves of devices with (A) PDPP as the active layer, (B) a PDPP/PCS blend as the active layer with 80 wt. % PDPP, (C) a PDPP/PCS blend as the active layer with 60 wt. % PDPP, (D) a PDPP/PCS blend as the active layer with 40 wt. % PDPP, and (E) a PDPP/PCS blend as the active layer with 20 wt. % PDPP.

FIG. 12(F) shows data related to the saturation mobility of devices with PDPP/PCS blends as the active layer. Error bars denote the standard deviation from measuring 10 devices per blend.

FIG. 13(A) shows a graph of adhesion strength as a function of weight percent of P3HT in the blended films.

FIGS. 13(B)-(E) show atomic force microscopy height images of (B) 0 wt. % P3HT, (C) 25 wt. % P3HT, (D) 50 wt. % P3HT, and (E) 75 wt. % P3HT films.

FIG. 14(A) shows a graph of adhesion strength as a function of weight percent of PDPP in the blended films.

FIGS. 14(B)-(E) shows atomic force microscopy height images of (B) 0 wt. % PDPP films, (C) 20 wt. % PDPP films, (D) 60 wt. % PDPP films, and (E) 80 wt. % PDPP films.

FIG. 15 shows 2D GIWAXS data from (A) 100 wt. % PBTTT films, (B) 80 wt. % PBTTT films, (C) 60 wt. % PBTTT films, (D) 40 wt. % PBTTT films, (E) 20 wt. % PBTTT films, and (F) 0 wt. % PBTTT films.

FIG. 16 shows 2D GIWAXS data from (A) 100 wt. % P3HT films, (B) 75 wt. % P3HT films, (C) 50 wt. % P3HT films, (D) 25 wt. % P3HT films, and (E) 0 wt. % P3HT films.

FIG. 17 shows 2D GIWAXS data from (A) 100 wt. % PDPP films, (B) 80 wt. % PDPP films, (C) 60 wt. % PDPP films, (D) 40 wt. % PDPP films, (E) 20 wt. % PDPP films, and (F) 0 wt. % PDPP films.

FIG. 18 shows 1D GIWAXS (A) out-of-plane profiles and (B) in-plane profiles from PBTTT/PCS films. Data were normalized by exposure time, film thickness, and concentration of conjugated polymer.

FIG. 19 shows a 1D GIWAXS of (A) out-of-plane profiles and (B) in-plane profiles from P3HT/PCS films. Spectra were normalized by exposure time, film thickness, and concentration of conjugated polymer.

FIG. 20 shows a 1D GIWAXS (A) out-of-plane profiles and (B) in-plane profiles from PDPP/PCS films. Spectra were normalized by exposure time, film thickness, and concentration of conjugated polymer.

FIG. 21 shows GIWAXS intensities vs polar angle χ at the (200) peak of (A) PBTTT/PCS blend films, (B) P3HT/PCS blend films, and (C) PDPP/PCS blend films. Spectra were normalized by exposure time, film thickness, and concentration of conjugated polymer.

FIG. 22 shows atomic force microscopy height images of (A) 0 wt. % PBTTT (RMS Roughness=37.3 nm) films, and (B) 80 wt. % PBTTT (RMS Roughness=5.67 nm) films.

FIG. 23 shows a surface time-of-flight secondary ion mass spectrometry (ToF-SIMS) negative ion spectra of (A) 0 wt. % PBTTT films, and (B) 100 wt. % PBTTT films. m/e=135 was used as a marker for PCS.

FIG. 24 shows surface ToF-SIMS images of (A) 0 wt. % PBTTT films, (B) 20 wt. % PBTTT films, (C) 40 wt. % PBTTT films, (D) 60 wt. % PBTTT films, and (E) 80 wt. % PBTTT films at m/e=135. These images were generated by summing the m/e 135 signal over the thickness of the entire profile. Scale bar equals 10 μm.

FIG. 25 shows angle resolved XPS measurements of (A) 0 wt. % PBTTT films, and (B) 80 wt. % PBTTT films at 30° and 80° takeoff angles. The signal on the left side of the plot represents the O Is signal coming from PCS. The signal on the right side of the plot represents the S 2p signal coming from PBTTT.

FIG. 26 shows angle resolved XPS measurements of (A) 20 wt. % PBTTT films, (B) 40 wt. % PBTTT films, (C) 60 wt. % PBTTT films, and (D) 100 wt. % PBTTT films at 30° and 80° takeoff angles. The signal on the left side of the plot represents the O Is signal coming from PCS. The signal on the right side of the plot represents the S 2p signal coming from PBTTT.

FIG. 27 shows angle resolved XPS measurements of (A) 0 wt. % P3HT films, (B) 25 wt. % P3HT films, (C) 50 wt. % P3HT films, (D) 75 wt. % P3HT films, and (E) 100 wt. % P3HT films at 30° and 80° takeoff angles. The signal on the left side of the plot represents the O Is signal coming from PCS. The signal on the right side of the plot represents the S 2p signal coming from P3HT.

FIG. 28 shows angle resolved XPS measurements of (A) 0 wt. % PDPP films, (B) 20 wt. % PDPP films, (C) 40 wt. % PDPP films, (D) 60 wt. % PDPP films, (E) 80 wt. % PDPP films, and (F) 100 wt. % PDPP films at 30° and 80° takeoff angles. The peak represents the S 2p signal coming from PDPP.

FIG. 29 shows XPS profiles for PBTTT/PCS blends that vary in composition near the oxygen and sulfur edges.

### DETAILED DESCRIPTION

For the purpose of promoting an understanding of the principles of the present disclosure, reference will now be made to the embodiments illustrated in the drawings and specific language will be used to describe the same. It will nevertheless be understood that no limitation of scope is intended by the description of these embodiments. On the contrary, this disclosure is intended to cover alternatives, modifications, and equivalents as may be included within the spirit and scope of this application as defined by the appended claims. As previously noted, while this technology may be illustrated and described in one or more preferred embodiments, the compositions, systems and methods hereof may comprise many different configurations, forms, materials, and accessories.

The present disclosure provides blended polymers, devices comprising such polymers, and methods for manufacturing the same. In certain embodiments, a blended polymer comprises a blended poly(vinyl catechol-styrene) (PCS) comprising three different kinds of conjugated polymers, which can be used to fabricate organic thin-film transistors (OTFTs) that exhibit strong adhesive properties. This approach can provide multifunctional thin films that perform as semiconductors and exhibit “sticky” properties. Devices containing these polymers as the active layer can exhibit only modest drop-off in mobility with respect to the adhesive polymer, for example, up to roughly half an order of magnitude.

Previous work has developed polymers that mimic the adhesive protein that mussels use for strong underwater adhesion. Westwood et al., Simplified polymer mimics of cross-linking adhesive proteins, Macromolecules 40 (11): 3960-3964 (2007). The amino acid 3,4-dihydroxyphenylalanine (DOPA), which is found in adhesive polypeptides, relies on several types of covalent and non-covalent bonding for strong adhesion to a variety of surfaces. DOPA groups enable proteins to bond to surfaces via hydrogen bonds and metal chelation, amongst several other interactions. To mimic DOPA within adhesive proteins, 3,4-dihydroxystyrene can be distributed along a polymeric styrenic backbone, resulting in PCS. See, e.g., Matos-Pérez et al., Polymer composition and substrate influences on the adhesive bonding of a biomimetic, cross-linking polymer, J Am Chemical Soc′y 134 (22): 9498-9505 (2012); Meredith et al., Enhancing the adhesion of a biomimetic polymer yields performance rivaling commercial glues, Advanced Functional Materials 24 (21): 3259-3267 (2014). Oxidation of these pendant dihydroxyphenyl (i.e., catechol) groups can facilitate cross-linking to provide cohesive interactions. PCS generally is a biomimetic polymer that can bond in both dry and wet conditions, can be used as a thin-coat primer, and has a long shelf life.

These kinds of biomimetic polymers can have significantly stronger underwater adhesion as compared to conventional products. Common epoxies have an underwater adhesion strength of about 1 MPa, whereas the biomimetic polymers hereof, under optimized conditions, can have a significantly stronger underwater adhesion strength of about 3 MPa. North et al., High strength underwater bonding with polymer mimics of mussel adhesive proteins, ACS Applied Materials & Interfaces 9 (8): 7866-7872 (2017). Because of their substantial underwater adhesion strength, they can enable a variety of bioelectronic applications.

In certain embodiments, a blended polymer is provided. The polymer can comprise a blend of a PCS and at least one conjugated polymer. A conjugated polymer comprises alternating single and double bonds along its backbone, which can create an extended system of Π-electrons.

The conugated polymer can be at least one poly(alkyl-thiophene) derivative or at least one high-performance donor-acceptor polymer. The poly(alkyl-thiophene) derivative can comprise P3HT or PBTTT. The poly(alkyl-thiophene) derivatie can comprise a conductive polymer.

A high performance donor-acceptor polymer is a conjugated polymer designed to optimize its electrical properties and can be synthesized by alternating electron-rich donor units with electron-deficient acceptor units along the polymer backbone to create an internal charge-transfer mechanism that can enhance the performance of the polymer. The high-performance donor-acceptor polymer can comprise PDPP. The high-performance donor-acceptor polymer can comprise poly[4,8-bis(2-ethylhexyloxy)benzo[1,2-b: 4,5-b′]dithiophene-thieno[3,4-b]thiopehne] (PTB7) or poly[4,8-bis(2-ethylhexyl)oxy]benzo[1,2-b: 5-b′]dithiophene-thieno[3,4-b]thiopehne] (PBDTTT).

The at least one poly(alkyl-thiophene) derivative or at least one a high-performance donor-acceptor polymer can be present in the polymer between about 20 weight percent (wt. %) to about 99 wt. % of the overall polymer. In certain embodiments, the at least one poly(alkyl-thiophene) derivative or at least one a high-performance donor-acceptor polymer can be present in the polymer between about 25 wt. % to about 90 wt. %. In certain embodiments, the at least one poly(alkyl-thiophene) derivative or at least one a high-performance donor-acceptor polymer is present in the polymer between about 25 wt. % to about 95 wt. % (such as 25-95 wt. %, about 25 wt. % to about 95 wt. %, or 25 wt % to about 95 wt. %). In certain embodiments, the at least one poly(alkyl-thiophene) derivative or at least one a high-performance donor-acceptor polymer is present in the polymer between about 30 wt. % to about 90 wt. % (such as 30-90 wt. %, about 30 wt. % to about 90 wt. %, or 30 wt % to about 90 wt. %). In certain embodiments, the at least one poly(alkyl-thiophene) derivative or at least one a high-performance donor-acceptor polymer is present in the polymer between about 35 wt. % to about 85 wt. % (such as 35-85 wt. %, about 35 wt. % to about 85 wt. %, or 35 wt % to about 85 wt. %). In certain embodiments, the at least one poly(alkyl-thiophene) derivative or at least one a high-performance donor-acceptor polymer is present in the polymer between about 40 wt. % to about 80 wt. % (such as 40-80 wt. %, about 40 wt. % to about 80 wt. %, or 40 wt % to about 80 wt. %). In certain embodiments, the at least one poly(alkyl-thiophene) derivative or at least one a high-performance donor-acceptor polymer is present in the polymer between about 45 wt. % to about 75 wt. % (such as 45-75 wt. %, about 45 wt. % to about 75 wt. %, or 45 wt % to about 75 wt. %). In certain embodiments, the at least one poly(alkyl-thiophene) derivative or at least one a high-performance donor-acceptor polymer is present in the polymer between about 50 wt. % to about 70 wt. % (such as 50-70 wt. %, about 50 wt. % to about 70 wt. %, or 50 wt % to about 70 wt. %). In certain embodiments, the at least one poly(alkyl-thiophene) derivative or at least one a high-performance donor-acceptor polymer is present in the polymer between about 55 wt. % to about 65 wt. % (such as 55-65 wt. %, about 55 wt. % to about 65 wt. %, or 55 wt % to about 65 wt. %). In certain embodiments, the at least one poly(alkyl-thiophene) derivative or at least one a high-performance donor-acceptor polymer is present in the polymer at about 60 wt. % (such as 60 wt. %). The ranges specified in this paragraph are inclusive of the stated end points and specifically include all 1 wt. % increments within the specified ranges.

In certain embodiments, the poly(alkyl-thiophene) derivative comprises P3HT and is present in at or about 10-25 wt. % of the polymer. In certain embodiments, the P3HT comprises about 10-24 wt. % of the polymer. In certain embodiments, the P3HT comprises about 11-23 wt. % of the polymer. In certain embodiments, P3HT comprises about 12-22 wt. % of the polymer. In certain embodiments, the P3HT comprises about 13-21 wt. % of the polymer. In certain embodiments, the P3HT comprises about 14-20 wt. % of the polymer. In certain embodiments, the P3HT comprises about 15-19 wt. % of the polymer. In certain embodiments, the P3HT comprises about 16-18 wt. % of the polymer. The ranges specified in this paragraph are inclusive of the stated end points and specifically include all 1 wt. % increments within the specified ranges.

In certain embodiments, PDPP comprises at or about 16-65 wt. % of the polymer. In certain embodiments, PDPP comprises at or about 60 wt. % of the polymer. In certain embodiments, PDPP comprises at or about 20-60 wt. % of the polymer. In certain embodiments, PDPP comprises at or about 25-55 wt. % of the polymer. In certain embodiments, PDPP comprises at or about 30-50 wt. % of the polymer. In certain embodiments, PDPP comprises at or about 35-45 wt. % of the polymer. The ranges specified in this paragraph are inclusive of the stated end points and specifically include all 1 wt. % increments within the specified ranges.

The blended polymers can exhibit both semiconductive and adhesive properties. In certain embodiments, the maximum adhesion strength for the polymer is at or about 4.3 MPa (e.g., in the PBTTT/PCS polymer system). In certain embodiments, the maximum adhesion strength for the polymer is about 0.05 MPa to about 4.5 MPa (e.g., 0.05 MPa to 4.5 MPa). In certain embodiments, the maximum adhesion strength for the polymer is about 0.1 MPa to about 4.4 MPa (e.g., 0.1 MPa to 4.4 MPa). In certain embodiments, the maximum adhesion strength for the polymer is about 0.2 MPa to about 4.3 (e.g., 0.2 MPa to 4.3 MPa). In certain embodiments, the adhesion strength for the polymer is about 0.4 MPa to about 4.2 MPa (e.g., 0.4 MPa to 4.2 MPa). In certain embodiments, the adhesion strength for the polymer is about 0.5 MPa to about 4.1 MPa (e.g., 0.5 MPa to 4.1 MPa). In certain embodiments, the adhesion strength for the polymer is about 0.6 MPa to about 4.0 MPa (e.g., 0.6 MPa to 4.0 MPa). In certain embodiments, the adhesion strength for the polymer is about 0.7 MPa to about 3.9 MPa (e.g., 0.7 MPa to 3.9 MPa). In certain embodiments, the adhesion strength for the polymer is about 0.8 MPa to about 3.8 MPa (e.g., 0.8 MPa to 3.8 MPa). In certain embodiments, the adhesion strength for the polymer is about 0.9 MPa to about 3.7 MPa (e.g., 0.9 MPa to 3.7 MPa). In certain embodiments, the adhesion strength for the polymer is about 1.0 MPa to about 3.6 MPa (e.g., 1.0 MPa to 3.6 MPa). In certain embodiments, the adhesion strength for the polymer is about 1.1 MPa to about 3.5 MPa (e.g., 1.1 MPa to 3.5 MPa). In certain embodiments, the adhesion strength for the polymer is about 1.2 MPa to about 3.4 MPa (e.g., 1.2 MPa to 3.4 MPa). In certain embodiments, the adhesion strength for the polymer is about 1.3 MPa to about 3.3 MPa (e.g., 1.3 MPa to 3.3 MPa). In certain embodiments, the adhesion strength for the polymer is about 1.4 MPa to about 3.2 MPa (e.g., 1.4 MPa to 3.2 MPa). In certain embodiments, the adhesion strength for the polymer is about 1.5 MPa to about 3.1 MPa (e.g., 1.5 MPa to 3.1 MPa). In certain embodiments, the adhesion strength for the polymer is about 1.6 MPa to about 3.0 MPa (e.g., 1.6 MPa to 3.0 MPa). In certain embodiments, the adhesion strength for the polymer is about 1.7 MPa to about 2.9 MPa (e.g., 1.7 MPa to 2.9 MPa). In certain embodiments, the adhesion strength for the polymer is about 1.8 MPa to about 2.8 MPa (e.g., 1.8 MPa to 2.8 MPa). In certain embodiments, the adhesion strength for the polymer is about 1.9 MPa to about 2.7 MPa (e.g., 1.9 MPa to 2.7 MPa). In certain embodiments, the adhesion strength for the polymer is about 2.0 MPa to about 2.6 MPa (e.g., 2.0 MPa to 2.6 MPa). In certain embodiments, the adhesion strength for the polymer is about 2.1 MPa to about 2.5 MPa (e.g., 2.1 MPa to 2.5 MPa). In certain embodiments, the adhesion strength for the polymer is about 2.2 MPa to about 2.4 MPa (e.g., 2.2 MPa to 2.4 MPa). The ranges specified in this paragraph are inclusive of the stated end points and specifically include all 0.05 increments within the specified ranges.

An OTFT is also provided that comprises the polymers (e.g., polymer blends) described herein. It will be understood that there is not a restriction on the laminated structure of the OTFT; it can be set in accordance with various well-known structures. However, by way of example, in certain embodiments, the OTFT can comprise an active layer (e.g., an organic semiconductor active layer) comprising a polymer blend hereof cast over at least two electrodes, a dielectric layer, and a substrate. Multiple OTFTs hereof can also be stacked in a 3D architecture as is known in the art.

In certain embodiments, the OTFT comprises an active layer, an insulating (e.g., dielectric) layer, and two electrodes arranged (e.g., sequentially) on an upper surface of a lowermost substrate (bottom gate/top contact type). The two electrodes can be provided on a surface of the active layer and arranged separately from each other.

The substrate can be the support of the active layer and electrodes. The substrate can comprise any well-known material that is suitable for the particular application including, for example and without limitation, a polyester film (such as a polyethylene napthalate (PEN) and/or polyethylene terephthalate (PET)), a cycloolefin polymer film, a polycarbonate film, a triacetyl cellulose (TAC) film, polyamide film, and/or those obtained by bonding polymer films to ultrathin glass, ceramic, silicon, quartz, and the like. In certain embodiments, the substrate comprises silicon. The substrate can comprise heavily doped p-type silicon. In certain embodiments, the substrate is one or more heavily doped p-type Si wafers comprising a thermally grown SiO₂ layer. In certain embodiments, the thermally grown SiO₂ layer is about 100 nm to about 500 nm thick (such as about 100 nm to 500 nm thick, 100 nm to about 500 nm thick, or 100-500 nm thick), wherein the specified ranges are inclusive of the stated end points and specifically include all 1 nm increments therein. In certain embodiments, the thermally grown SiO₂ layer is about 300 nm thick (such as 300 nm thick).

The electrodes can comprise of a metal such as, for example, aluminum, gold, copper, cadmium, induium oxide, zinc-tin oxide, or the like, and/or alloy materials thereof. Any known conductive material can be used without particular limitation. In certain embodiments, the electrodes can comprise different metals. In certain embodiments, the electrodes can comprise the same metal. In certain embodiments, at least two of the electrodes comprise gold.

The thickeness of each electrode is not particularly limited. In certain embodiments, the thickness of an electrode can be about 10 nm to about 150 nm (such as, 10 nm to about 150 nm, about 10 nm to 150 nm, or 10 nm to 150 nm), inclusive of the stated end points and specifically including all 1 nm increments within the specified ranges. In certain embodiments, the electrodes are each about 100 nm thick.

The insulating layer can be a dielectric layer. The material constituting the insulating layer is not particularly limited provided the necessary insulating effect can be obtained. In certain embodiments, the insulating layer comprises a fluorine polymer insulating material such as silicon dioxide, silicon nitride, polytetrafluoroethylene (PTFE), CYTOP, polyester insulating materials, carbonate insulating materials, acrylic polymer insulating materials, epoxy resin insulating materials, polyimide insulating materials, polyvinylphenol resin insulating materials, polyparaxylylene resin insulating materials, and the like. In certain embodiments, the insulating material comprises polyvinylpyrrolidone (PVP) or poly(methyl methacyrlate) (PMMA).

The upper surface of the insulating layer can be surface treated. For example, the upper surface of the insulating layer can be treated by applying hexamethyldisilazane (HMDS) or octadecyltrichlorosilane (OTS) to a silicon dioxide surface. In certain embodiments, the insulating layer comprises a portion of (e.g., an upper layer of) the substrate. In certain embodiments, the insulating layer comprises a patterned layer applied to hte substrate using conventional double-layer lithography techniques.

The thickness of the insulating layer is not particularly limited, but when thinning is required, the thickness can be, for example about 10 nm to about 400 nm (such as 10 nm to 400 nm), inclusive of the stated end points of the range and specifically including all 1 nm increments within the specified range.

The active layer can comprise an organic semiconductor active layer comprising at least one of the blended polymers described herein. In certain embodiments, the active layer comprises at least one of the blended polymers hereof in addition to a polymer binder. The polymer binder can be any suitable polymer binder and can be present in an amount of 0 to 95% by mass, 5% to 90% by mass, 10% to 85% by mass, 15% to 80% by mass, 20% to 80% by mass, 25% to 75% by mass, 30% to 70% by mass, 35% to 65% by mass, 40% to 60% by mass, 45% to 55% by mass, or 50% by mass. The ranges stated in the foregoing sentence are inclusive of the stated end points and specifically include all 1% increments within the specified ranges.

There is no particular limitation in the thickness of the semiconductor active layer. In certain embodiments, the active layer can have a thickness of about 10 nm to about 400 nm (such as 10 nm to 400 nm), inclusive of the stated end points of the range and specifically including all 1 nm increments within the specified range.

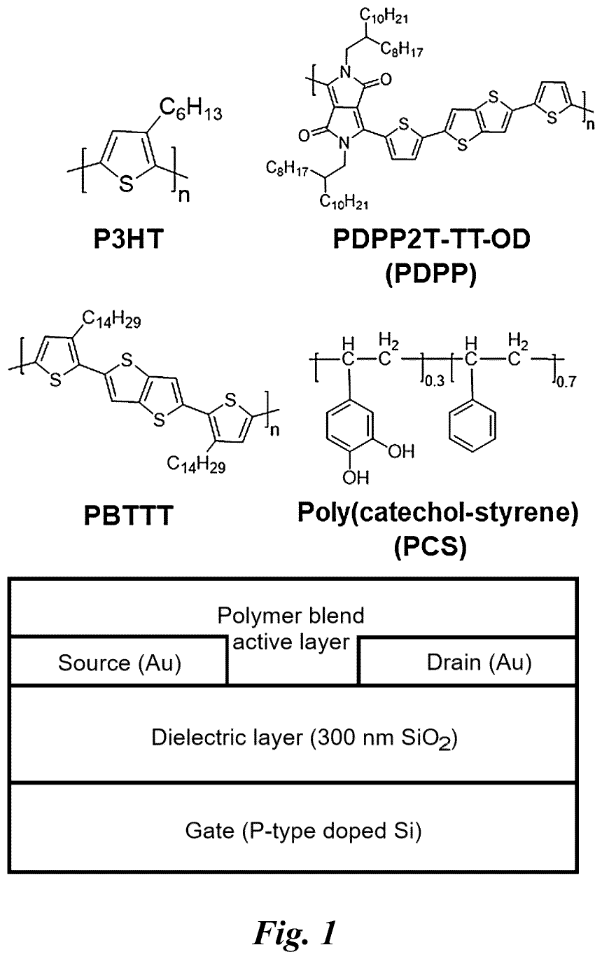

An example of the structure of the bottom gate/top contact type element is shown in FIG. 1. The substrate is disposed on the lowermost layer (labeled “Gate”), the electrodes are provided on a part of the upper surface, and the insulating layer is in contact with the substrate. Further, the semiconductor active layer is provided on an upper surface of the insulating layer and the at least two electrodes are disposed separately on a part of the upper surface of the insulating layer (e.g., forming a channel that is a current path therebetween and in which the blended polymers of the active layer can crystalize) and is insulated from the gate (i.e., the substrate). In certain embodiments, at least one of the electrodes is a drain and at least one of the electrodes is a source, and the substrate is the gate.

OTFTs fabricated using the polymers hereof can exhibit adhesion strength comparable to that of an epoxy concurrently with conductive properties. Adhesion strength can vary depending on composition of the active layer; from about 0.05 MPa to about 4.30 MPa (e.g., 0.05 MPa to 4.30 MPa) based on PBTTT/PCS blends, from 0.29 MPa to 4.29 MPa (e.g., 0.29 MPa to 4.29 MPa) based on P3HT/PCS, and from 0.30 MPa to 3.52 MPa (e.g., 0.30 MPa to 3.52 MPa) based on PDPP/PCS, wherein such ranges are inclusive of the stated end points and all 0.01 increments encompassed thereby. Thus, polymer blends hereof can be used for stable vertical stacking of OTFTs in 3D architectures or be used in applications that require adhesion onto wet surfaces, such as in bioelectronics.

Methods for preparing the OTFTs hereof are also provided. An OTFT can be prepared pursuant to any of the methods described in the Examples below. In certain embodiments, the preparation of an OTFT comprises depositing a polymer blend hereof (e.g., a polymer blend in solution) onto an insulating layer of or on a substrate (e.g., wherein the substrate comprises heavily doped p-type Si (100) wafers)) by way of spin coating, drop coating, blade coating, spraying, solution shear, silk-screen printing, or inkjet printing. The insulating layer can a thermally grown SiO₂ layer on the substrate. In certain embodiments, the insulating layer is 300 nm thick.

The two or more electrodes can be evaporated onto the substrate and patterned using methods commonly known in the art. In certain embodiments, the electrodes are evaporated onto the substrate and patterened using conventional double-layer lithography techniques.

Heating or ultraviolet irradiation processing can be performed on the polymer solution deposited on the insulating layer. For example, the deposited polymer solution on the substrate can be subjected to UV-Ozone treatment. In certain embodiments, the substrate can be surface-treated with either tetramethyl orthosilicate (TMOS) in hexadecane (e.g., 0.006 M TMOS where the polymer comprises a P3HT/PCS system) or octadecyltrichlorosilane (ODTS) in trichloroethylene (e.g., 0.01 M ODTS where the polymer comprises PBTTT/PCS & PDPP/PCS systems) for a period of time (e.g., 20 minutes at room temperature in a nitrogen-filled glovebox). The resulting OTFT can then be annealed (e.g., at 150° C. for 3 hours, at 140° C. for 12.5 minutes, or at 160° C. for 10 minutes).

In certain embodiments, a method of preparing an OTFT comprises: evaporating and patterning two or more electrodes onto a substrate; depositing a solution of any of the polymer blends described herein onto an insulating layer positioned over the substrate or onto the substrate directly; and processing the deposited polymer blend solution; wherein the resulting OTFT comprises a semiconductor active layer comprising the polymer blend, the two or more electrodes are in conductive communication with the semiconductive active layer, and at least a portion of the substrate comprises a gate.

Evaoprating and patterning the two or more electrodes can be performed using any suitable technology and/or processes known or hereinafter developed. For example, and without limitation, the patterning can be performed using double-layered lithography techniques.

The electrodes can comprise at least one source electrode and at least one drain electrode. In certain embodiments, one or more of the electrodes is formed, at least in part, of gold (Au). In certain embodiments, the electrodes comprise at least one gold source electrode and at least one gold drain electrode. In certain embodiments, the electrodes are each about 100 nm thick. The electrodes can comprise any of the electrodes described herein.

The electrodes can be positioned on the substrate. The substrate can comprise a plurality of wafers (e.g., 100 stacked wafers). In certain embodiments, the substrate comprises heavily doped p-type Si wafers. In certain embodimenst, the substrate further comprises an insulating layer. The insulating layer can comprise, for example, a 300 nm thick, thermally grown SiO₂ layer or an Si/SiO₂ layer. In certain embodiments, the substrate can be surface-treated (e.g., as described herein). In certain embodiments, the substrate comprises acid-etched aluminum.

A solution of blended polymer can then be directly deposited onto the substrate comprising the electrodes. Additionally or alternatively, the solution of blended polymer can be deposited onto an insulating layer of the substrate. The solution can be deposited using any now-known or hereinafter developed technique that is suitable. For example and without limitation, the depositing can be performed by spin coating, drop coating, blade coating, spraying, solution shear, silk-screen printing, or inkjet printing.

The solution of blended polymer can comprise any of the solutions and/or weight percentages of polymer blends described herein. In certain embodiments, the solution of blended polymer is produced by dissolving a conjugated polymer and an adhesive polymer in a solvent. The adhesive polymer can comprise PCS. The conjugated polymer can comprise at least one poly(alkyl-thiophene) derivative or at least one high-performance donor-acceptor polymer. The conjugated polymer can comprise P3HT. The conjugated polymer can comprise PBTTT. The conjguated polymer can comprise PDPP. The solvent can comprise any suitable solvent. In certain embodiments, the solvent is 1,2,4-trichlorobenzene. In certain embodiments, the solvent is 1,2-dichlorobenzene. Solutions of the blended polymers can also be combined to achieve the desired weight percent blend of the polymers.

Once deposited, the polymer blend solution is then processed. In certain embodiments, heating or ultraviolet irradiation processing is performed on the polymer solution deposited on the insulating layer and/or the substrate. Processing can comprise UV-ozone treatment, for example. In certain embodiments, the substrate can be surface-treated with either tetramethyl orthosilicate (TMOS) in hexadecane (e.g., 0.006 M TMOS where the polymer comprises a P3HT/PCS system) or octadecyltrichlorosilane (ODTS) in trichloroethylene (e.g., 0.01 M ODTS where the polymer comprises PBTTT/PCS & PDPP/PCS systems) for a period of time (e.g., 20 minutes at room temperature in a nitrogen-filled glovebox). The resulting OTFT can then be annealed (e.g., at 150° C. for 3 hours, at 140° C. for 12.5 minutes, or at 160° C. for 10 minutes).

### General

All patents, patent application publications, journal articles, textbooks, and other publications mentioned in the specification are indicative of the level of skill of those in the art to which the disclosure pertains.

Numerous specific details are set forth herein to provide a thorough understanding of the present disclosure. Particular examples may be implemented without some or all of these specific details. It will be understood that the disclosure is presented in this manner merely for explanatory purposes and the principles and embodiments described herein may be applied to polymers and/or OTFTs that have configurations other than as specifically described herein. Indeed, it is expressly contemplated that the polymers and OTFTs hereof can be tailored in furtherance of the desired application thereof.

Unless defined otherwise, all technical and scientific terms used herein have the same meaning as commonly understood by one of skill in the chemical and biological arts. The terms and expressions which are employed are used as terms of description and not of limitation. In this regard, where certain terms are defined, described, or discussed elsewhere in the “Detailed Description,” all such definitions, descriptions, and discussions are intended to be attributed to such terms. There also is no intention in the use of such terms and expressions of excluding any equivalents of the features shown and described or portions thereof. Furthermore, while subheadings, e.g., “Certain Definitions,” are used in the “Detailed Description,” such use is solely for ease of reference and is not intended to limit any disclosure made in one section to that section only; rather, any disclosure made under one subheading is intended to constitute a disclosure under each and every other subheading.

Although any methods and materials similar to or equivalent to those described herein can be used in the practice or testing of the subject of the present application, the preferred methods and materials are described herein.

When ranges are used herein for physical properties, such as molecular weight, or chemical properties, such as chemical formulae, all combinations and sub-combinations of ranges and specific embodiments therein are intended to be included unless expressly otherwise indicated.

It is recognized that various modifications are possible within the scope of the disclosure. Thus, although the present disclosure has been specifically disclosed in the context of preferred embodiments and optional features, those skilled in the art may resort to modifications and variations of the concepts disclosed herein. Such modifications and variations are considered to be within the scope of the disclosure as claimed herein.

It is therefore intended that this description and the appended claims will encompass all modifications and changes apparent to those of ordinary skill in the art based on this disclosure. For example, where a method of treatment or therapy comprises administering more than one treatment, compound, or composition to a subject, it will be understood that the order, timing, number, concentration, and volume of the administration is limited only by the medical requirements and limitations of the treatment (i.e., two treatments can be administered to the subject, e.g., simultaneously, consecutively, sequentially, alternatively, or according to any other regimen).

Additionally, in describing representative embodiments, the disclosure may have presented a method and/or process as a particular sequence of steps. To the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps disclosed herein should not be construed as limitations on the claims. In addition, the claims directed to a method and/or process should not be limited to the performance of their steps in the order written, and one skilled in the art can readily appreciate that the sequences may be varied and still remain within the spirit and scope of the present disclosure.

### Certain Definitions

The term “about,” when referring to a number or a numerical value or range (including, for example, whole numbers, fractions, and percentages), means that the number or numerical range referred to is an approximation within experimental variability (or within statistical experimental error), and thus the numerical value or range can vary between 1% and 10% of the stated number or numerical range (e.g., +/−5% to 10% of the recited value), provided that one of ordinary skill in the art would consider equivalent to the recited value (e.g., having the same function or result).

The disclosure may be suitably practiced in the absence of any element(s) or limitation(s), which is/are not specifically disclosed herein. Thus, for example, each instance herein of any of the terms “comprising,” “consisting essentially of,” and “consisting of” (and related terms such as “comprise” or “comprises” or “having” or “including”) can be replaced with the other mentioned terms. Likewise, the singular forms “a,” “an,” and “the” include plural references unless the context clearly dictates otherwise. Thus, for example, references to “the method” include one or more methods and/or steps of the type, which are described and/or which will become apparent to those ordinarily skilled in the art upon reading the disclosure. The term “substantially” can allow for a degree of variability in a value or range, for example, within 90%, within 95%, or within 99% of a stated value or of a stated limit of a range.

### EXAMPLES

The following examples serve to illustrate the present disclosure so as to provide those of ordinary skill in the art with a complete disclosure and description of how to make and use the embodiments hereof. The examples are not intended to limit the scope of the claimed invention in any way, nor are they intended to represent that the experiments below are all or the only experiments performed. Efforts have been made to ensure accuracy with respect to the numbers used (e.g., amounts, temperature, etc.), but some experimental errors and deviations should be accounted for. Unless otherwise indicated, parts are parts by weights, molecular weight is weight average molecular weight, temperature is in degrees Centigrade, and pressure is at or near atmospheric.

### Materials

Poly(3-hexylthiophene-2,5-diyl) (P3HT) (EE97802, M_{w}=36.6 kg/mol, Ð=2.0) was purchased from Merck & Co. (Darmstadt, Germany). Poly[2,5-bis(3-tetradecylthiophen-2-yl) thieno[3,2-b]thiophene] (PBTTT) (Product 753971, M_{w}=65.0 kg/mol, Ð=2.5) was purchased from MilliporeSigma (Burlington, MA).

Poly[2,5-(2-octyldodecyl)-3,6-diketopyrrolopyrrole-alt-5,5-(2,5-di(thien-2-yl) thieno[3,2-b]thiophene)] (PDPP) (M0311A2, M_{w}=204 kg/mol, Ð=3.1) was purchased from Ossila Otd. (Sheffield, England).

Poly[(3,4-dihydroxystyrene)-co-styrene] (M_{w}=64.3 kg/mol, Ð=2.3, percent catechol=29.8%) was synthesized in accordance with the methodologies described in Westwood et al. (2007), supra; Matos-Pérez et al. (2012), supra; Meredith et al. (2014), supra.

Anhydrous trichloroethylene, trichloro(octadecyl) silane (ODTS), anhydrous 1,2-Dichlorobenzene, and anhydrous 1,2,4-Trichlorobenzene were purchased from MilliporeSigma (Burlington, MA).

Hexadecane was purchased from Alfa Aesar Chemicals (Ward Hill, MA).

Trimethoxy (octadecyl) silane (TMOS) was purchased from Acros Organics (Veneto, Italy).

Heavily doped p-type Si (100) wafers from Process Specialties, Inc. (Pelham, AL) were used for GIWAXS, AFM, and AR-XPS. Heavily doped p-type Si (100) wafers with a 300 nm thick thermally grown SiO₂ layer from Process Specialties, Inc. (Pelham, AL) were used for OTFTs, bonding samples, and ToF-SIMS.

### Example 1

### OTFT Fabrication and Testing

Examplary conjugated and adhesive polymers and OTFT device architecture used in this study are shown in FIG. 1. Two alkyl-thiophene derivatives, poly(3-hexylthiophene-2,5-diyl) (P3HT) and poly[2,5-bis(3-tetradecylthiophen-2-yl) thieno[3,2-b]thiophene] (PBTTT), along with a high-performance donor-acceptor polymer, poly[2,5-(2-octyldodecyl)-3,6-diketopyrrolopyrrole-alt-5,5-(2,5-di(thien-2-yl) thieno[3,2-b]thiophene)] (PDPP), were used to fabricate active layers of OTFTs. PCS was blended with conjugated polymers at various concentrations and films were cast on bottom gate, bottom contact substrates.

More specifically, solutions for OTFTs were prepared by dissolving the conjugated polymer and adhesive polymer in the corresponding solvent (1,2,4-Trichlorobenzene for P3HT/PCS and 1,2-Dichlorobenzene for PBTTT/PCS and PDPP/PCS) individually at a concentration of 10 mg/ml overnight on a 45° C. hotplate. Individual solutions were then distributed to get the correct weight percent blends. These blend solutions were then stirred on a 45° C. hotplate for about 2 hours.

The OTFT substrates comprised heavily doped p-type Si (100) wafers with 300 nm thick thermally grown SiO₂ layer. 100 nm thick gold source and drain electrodes were evaporated onto the substrate and patterned using conventional double-layer lithography techniques at the Pennsylvania State Materials Research Institute Nanofabrication Laboratory (University Park, PA).

Substrates were cleaned with isopropanol and dried with dry air. They were then subjected to UV-Ozone for 20 minutes. After UV-Ozone, OTFT substrates were surface-treated with either 0.006 M TMOS in hexadecane (P3HT/PCS system) overnight at room temperature in air or 0.01 M ODTS in trichloroethylene (PBTTT/PCS & PDPP/PCS systems) for 20 minutes at room temperature in a nitrogen-filled glovebox. Substrates were then cleaned using isopropanol (P3HT/PCS system) or toluene and isopropanol (PBTTT/PCS and PDPP/PCS systems). TMOS treated substrates were then dried with air. ODTS treated substrates were dried with air and annealed at 120° C. for 20 minutes. Solutions were stirred at 90° C. prior to deposition. P3HT/PCS were spin coated at 1000 RPM for 4 minutes after letting deposited solution wet on the surface for 40 seconds. PBTTT/PCS were spin coated at 2000 RPM for 2 minutes. PDPP/PCS were spin coated at 1500 RPM for 2 minutes.

Devices were then annealed at the following conditions. P3HT/PCS were annealed at 150° C. for 3 hours. PBTTT/PCS were annealed at 140° C. for 12.5 minutes. PDPP/PCS were annealed at 160° C. for 10 minutes.

Devices were fabricated in bottom gate, bottom contact configurations. Devices were then tested using a Keithley 4200-SCS to obtain transfer curves in the saturation regime and output curves. Mobility equation (Equation 1) in the saturation regime was used to extract hole mobility:

μ_{diff,sat}(V_{G})=(∂\sqrt{I_{D}}/∂V_{G})²*2L/W*C (1),

where I_{D} is current between the source and drain electrodes, L and W is length and width of the channel, μ_{diff, sat} is differential charge mobility in the saturation regime, C is capacitance of the dielectric, and V_{G} is gate voltage. For all devices tested, L=320 μm and W=220 μm.

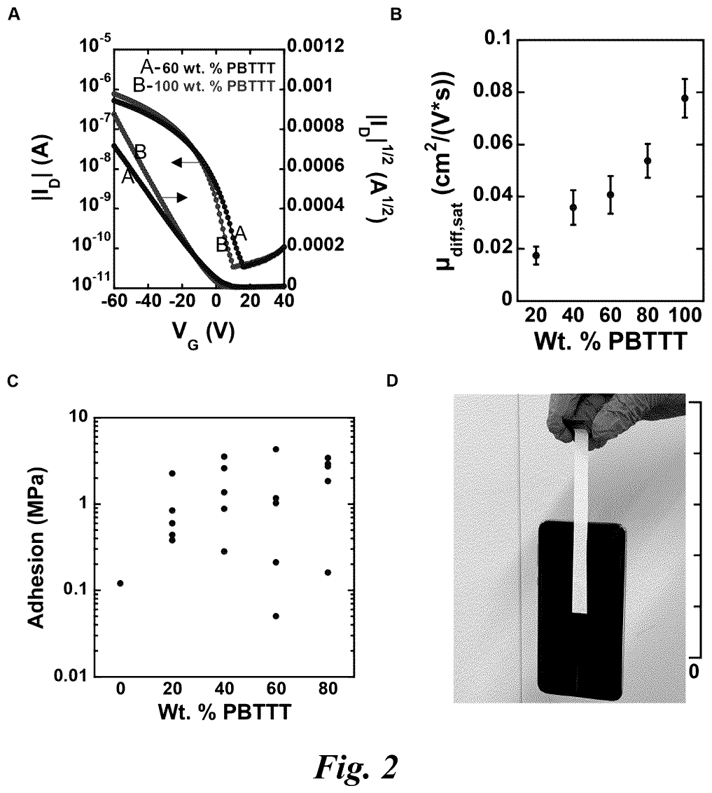

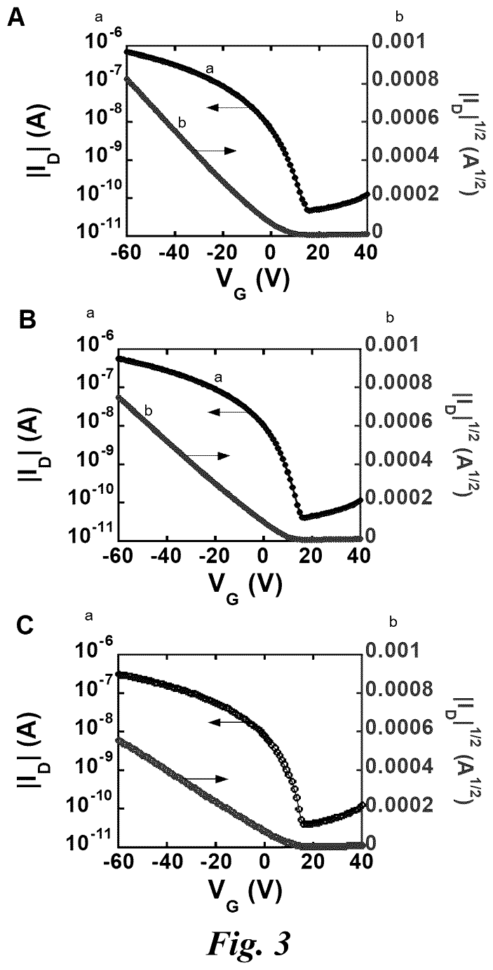

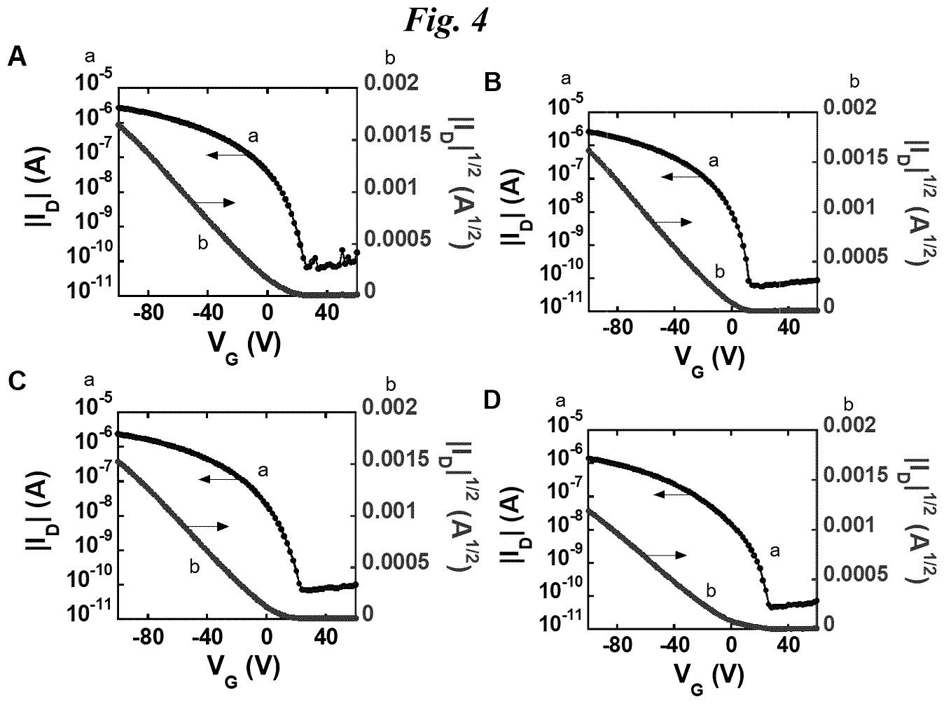

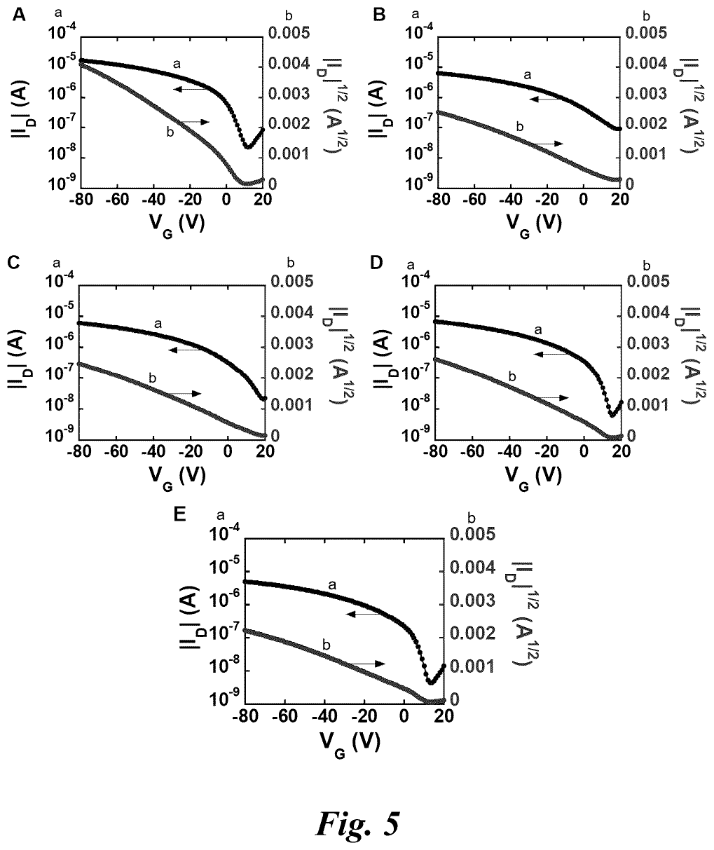

From the transfer curves of devices based on the above blends (FIGS. 2-5), the threshold voltage for PBTTT/PCS devices shifted from −3.65 V to 9.55 V, for P3HT/PCS devices the shift was from 5.97 V to −1.32 V, and for PDPP/PCS devices the threshold voltage increased from 9.52 V to 18.9 V when PCS was added.

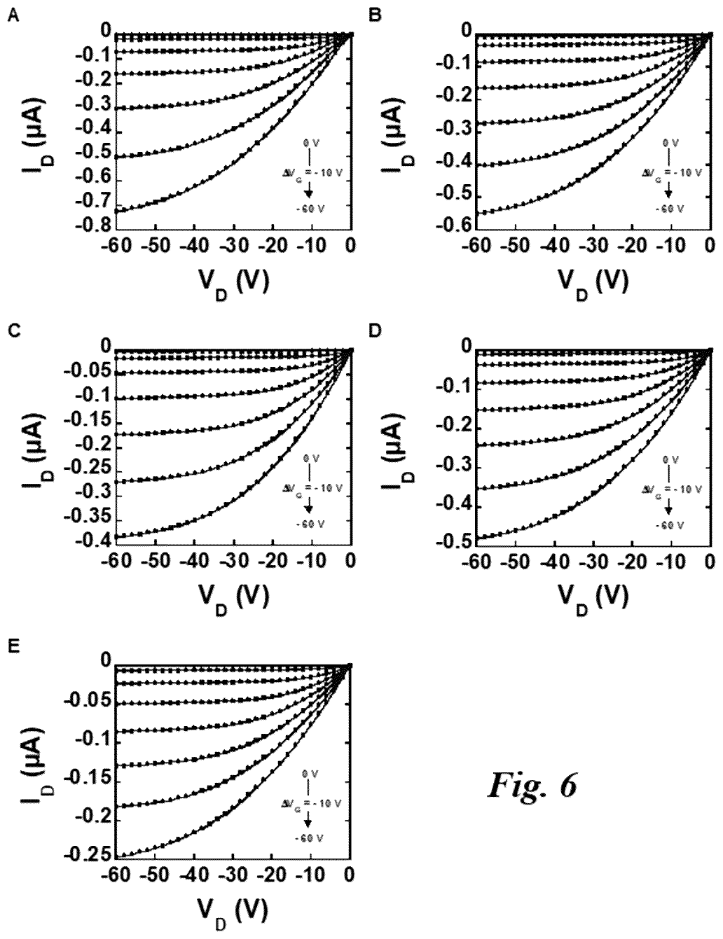

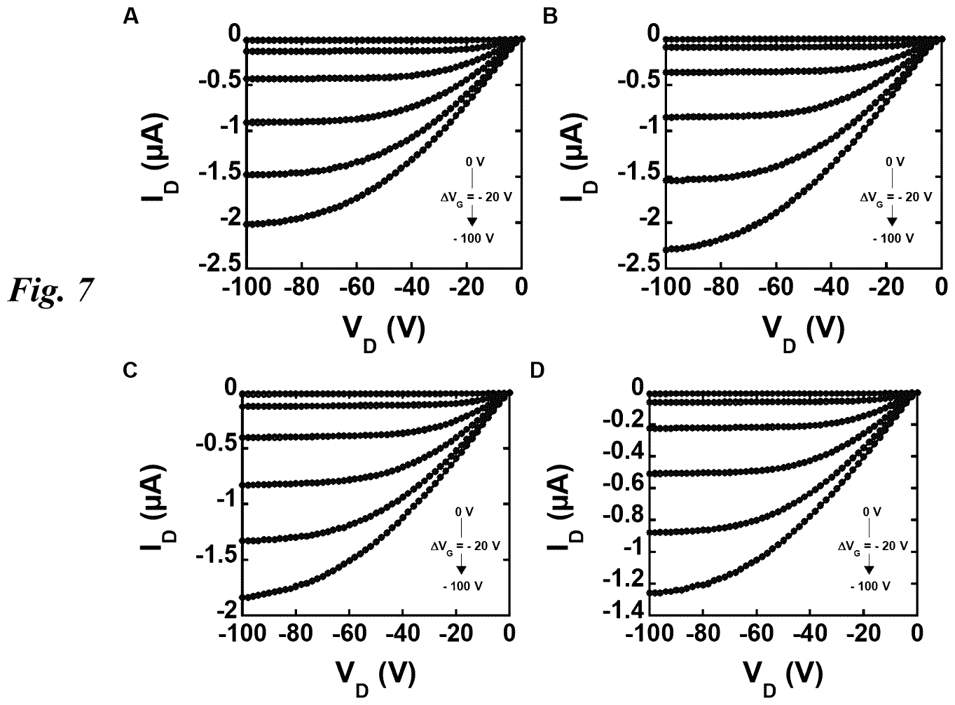

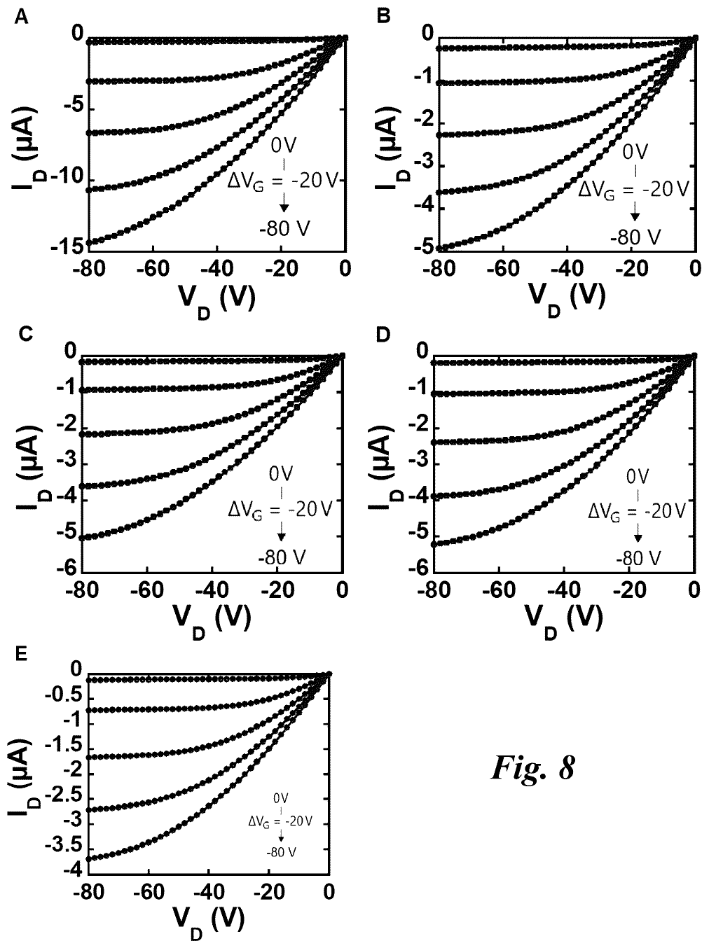

Output curves of PBTTT/PCS blend (FIG. 6), P3HT/PCS blend (FIG. 7), and PDPP/PCS blend (FIG. 8) OFETs have a linear regime and a saturation regime without a major sign of a contact resistance problem. In addition, pinch off points occurred at the correct drain voltage.

Mobility values were obtained in the region where mobility was roughly constant with gate voltage. Devices consisting of pure conjugated polymer had performance values similar to the ones reported in literature. Boufflet et al., Using molecular design to increase hole transport: Backbone fluorination in the benchmark material poly(2,5-bis(3-alkylthiophen-2-yl) thieno[3,2-b]-thiphene (pBTTT), Advanced Functional Materials 25 (45): 7038-7048 (2015); McCulloch et al., Liquid-crystalline semiconducting polymers with high charge-carrier mobility, National Materials 5:328 (2006); Chang et al., Enhanced mobility of poly(3-hexylthiophene) transistors by spin-coating from high-boiling-point solvents, Chemical Materials 16 (23): 4772-4776 (2004); Li et al., A high mobility p-type DPP-thieno[3,2,-b]thiophene copolymer for organic thin-film transistors, Advanced Materials 22 (43): 4862-4866 (2010).

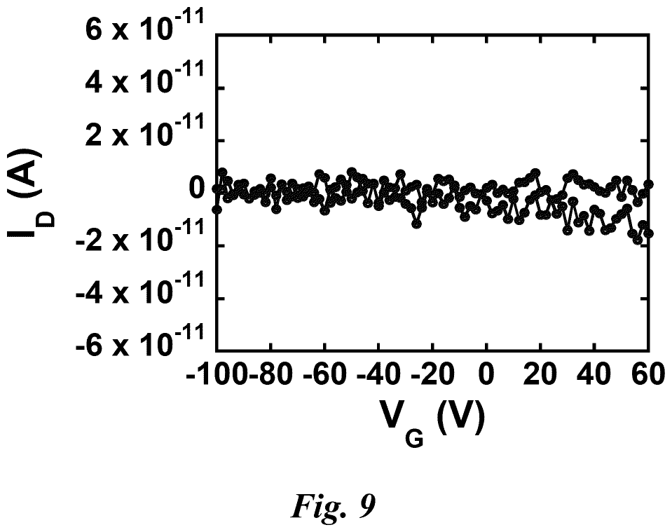

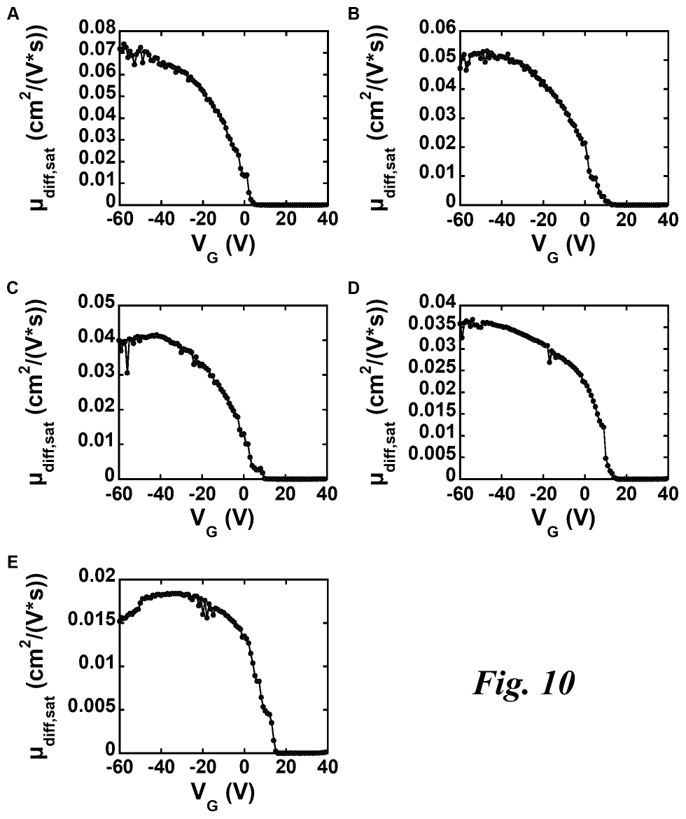

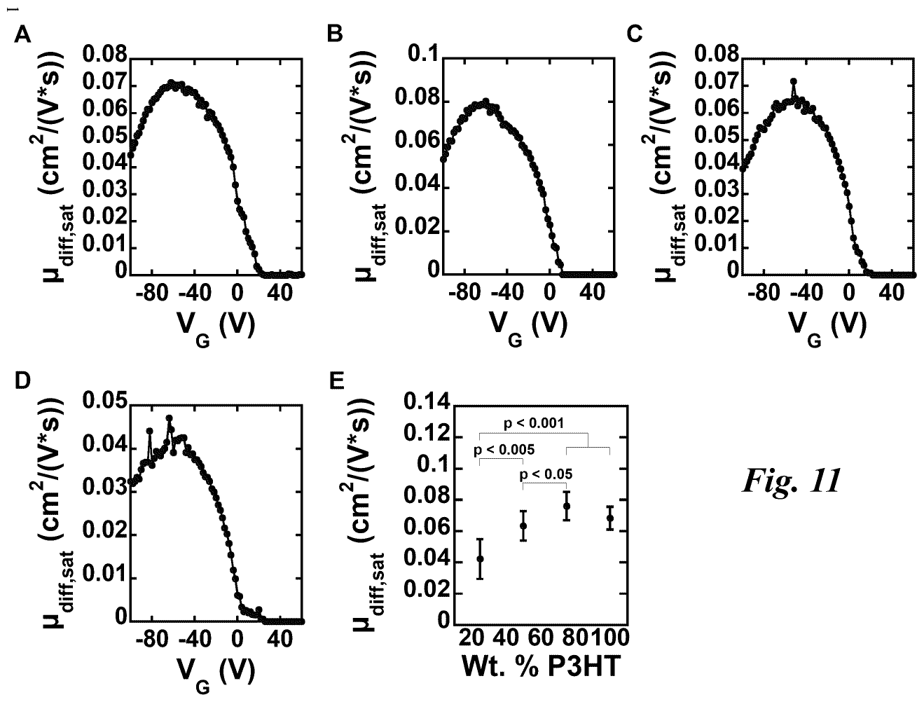

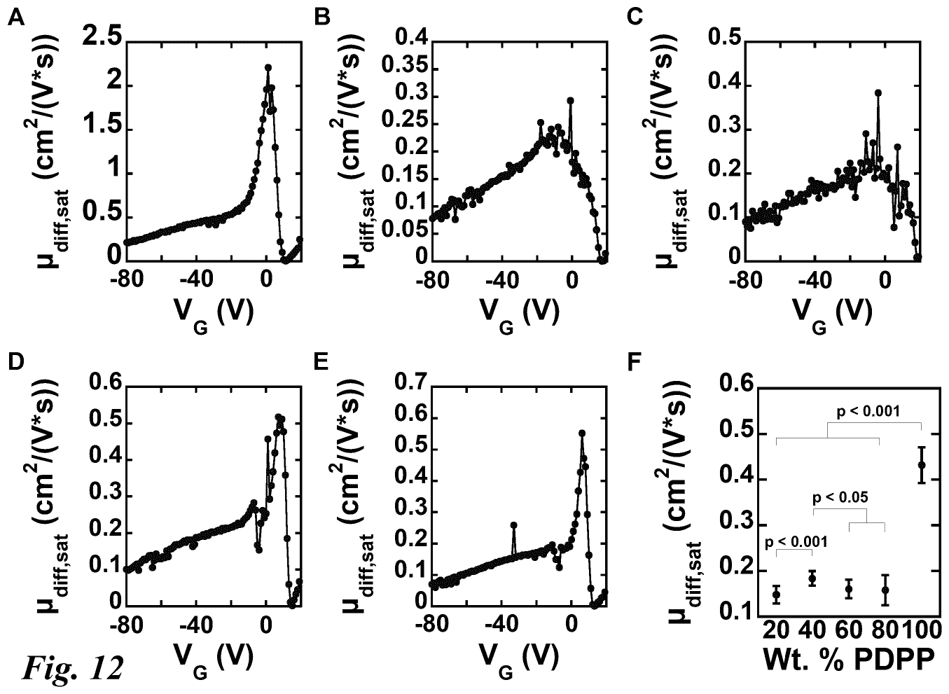

As expected, the PCS films did not conduct charge (FIG. 9). Once the adhesive polymer was added, charge mobilities decreased by roughly half an order of magnitude when going from pristine conjugated polymer to either 25 wt. % or 20 wt. % conjugated polymer (FIG. 2(B) and FIGS. 10-12). For PBTTT/PCS blends, mobilities constantly decrease from 0.0742 cm² V⁻¹ s⁻¹ to 0.0174 cm² V⁻¹ s⁻¹ when going from 100 wt. % PBTTT to 20 wt. % PBTTT. For P3HT/PCS blends, mobilities started at 0.0683 cm² V⁻¹ s⁻¹ for 100 wt. % P3HT and remain constant until 25 wt. % P3HT, where they decrease to 0.0421 cm² V⁻¹ s⁻¹. For PDPP/PCS blends, mobilities constantly decrease from 0.432 cm² V⁻¹ s⁻¹ to 0.148 cm² V⁻¹ s⁻¹ when going from 100 wt. % PDPP to 20 wt. % PDPP. A decrease in mobility as the amount of insulative material increased was expected. Although some decrease in charge mobility was observed, the decrease shown in FIG. 2(B) was modest, such that blend films exhibit reasonable charge transport for a wide range of compositions.

Plots of mobility versus gate voltage for the three blend systems show that there were three different TFT behaviors occurring (FIG. 2(B) and FIGS. 10-12). For PBTTT/PCS blends, an eventual plateau of mobility at high gate voltage was indicative of a power-law mobility. Liu et al., Device physics of contact issues for the overestimation and underestimation of carrier mobility in field-effect transistors, Physical Review Applied 8:034020 (2017). For P3HT/PCS blends, an increase then gradual decay in mobility represented a gradual decaying mobility. Id. For PDPP/PCS blends, the peak in the mobility plot (“kink” in the transfer curve) is reminiscent of a transition from a contact-limited device at low gate voltages. Bittle et al., Mobility overestimation due to gated contacts in organic field-effect transistors, Nature Communications 7:10908 (2016).

### Example 2

### Lap Shear Testing

A lap shear strength test was used to quantitatively characterize adhesive properties of blend films. Briefly, lap shear strength test samples were prepared similarly to how OTFTs were fabricated, except that bare Si/SiO₂ was used. Two spin coated samples were prepared for each bonding sample. Blend films were bonded with FM1202 Vacuum Mold Pressing Machine (Beijing Future Material Sci-Tech Co., Ltd., Beijing, China). One of the prepared samples was stacked on top of the other sample with both polymer film surfaces facing each other. One of the samples was made sure to be smaller than the other to ensure that the adjoining polymer surfaces overlap completely. Adjoined samples were then subjected to a constant pressure of 1 MPa and heated at 180° C. for 24 hours for the curing process.

After 24 hours, the sample was allowed to cool for 6 hours while still being pressed at a constant pressure of 1 MPa. The sample was then removed from the bonder. Bonded samples were then adhered to two American Society of Testing and Materials (ASTM) acid-etched aluminum substrates using commercial epoxy. The substrates were drilled on one end for use in lap shear adhesion testing. Bonded silicon/silicon dioxide wafers were allowed to cure to the aluminum for 24 hours for maximum hold. Lap shear samples were tested using an Instron 5544 with a 2 kN load cell. Pull rate was set to 2 mm/minute and allowed for complete failure of the bonded area.

Atomic force microscopy (AFM) was also performed on the samples to further assess adhesion strength. AFM samples were prepared similarly to how the GIWAXS samples were prepared (described below in Example 3). The samples were imaged with Bruker Dimension Icon Atomic Force Microscope using peak force tapping mode. The peak force set point was set at 1.5 nN.

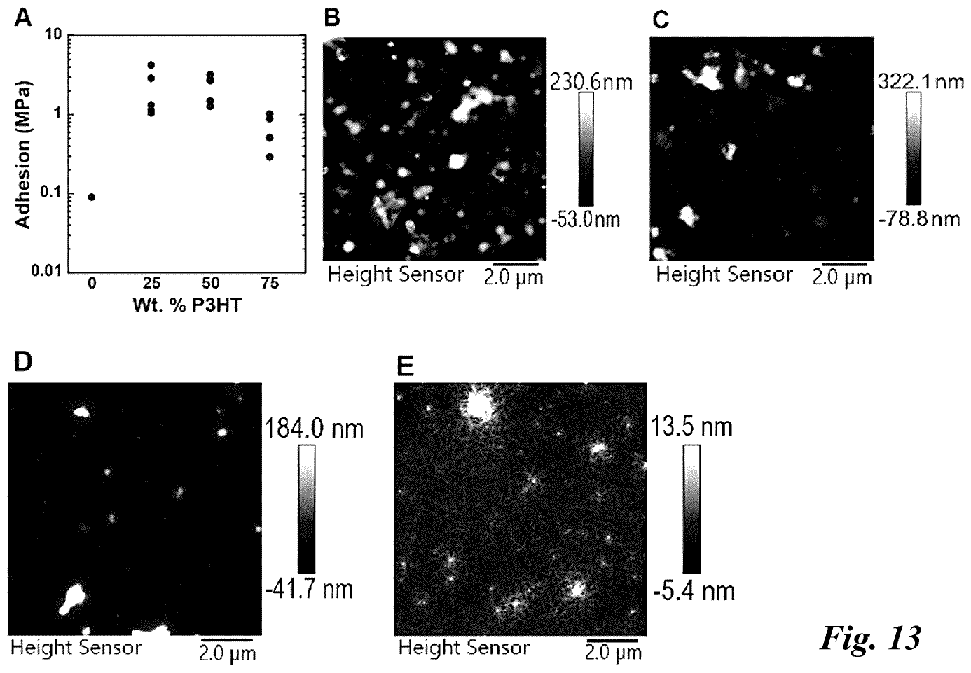

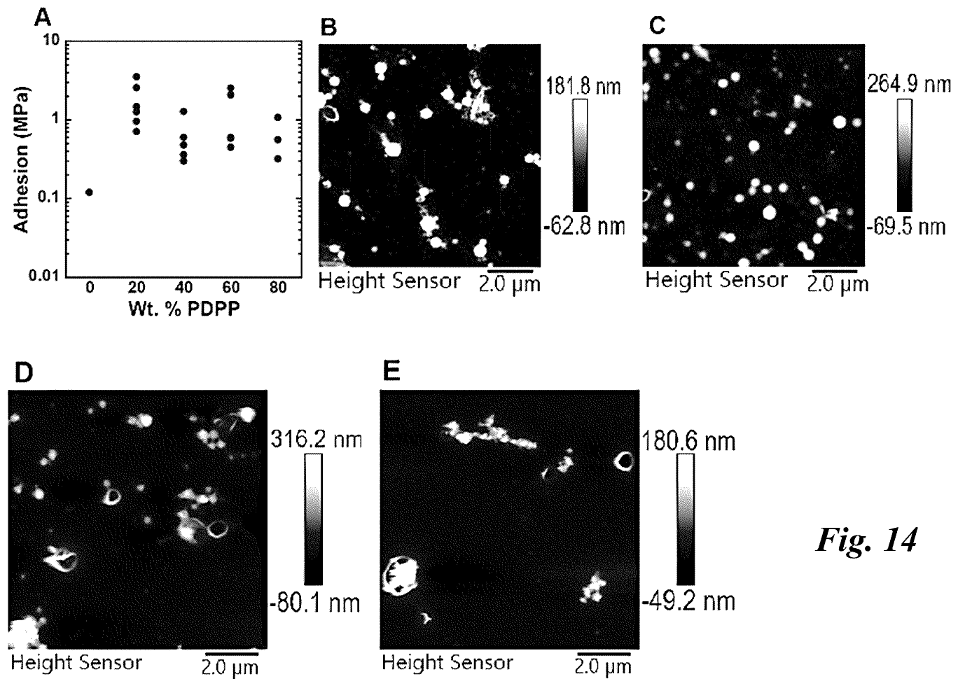

The PBTTT/PCS system exhibited adhesion from 0.05 MPa to 4.30 MPa (FIG. 2(C)), the P3HT/PCS system exhibited adhesion from 0.29 MPa to 4.23 MPa (FIG. 13(A)), and PDPP/PCS system can have adhesion from 0.30 MPa to 3.52 MPa (FIG. 14(A)). The maximum adhesion for each conjugated polymer/PCS blend was about one-half of what is measured for cyanoacrylate super glue when bonding aluminum. Matos-Pérez et al. (2012), supra.

As an example of the adhesion strength of these blends, bonded 60 wt. % PDPP films (0.5 inch×0.5 inch in bonding area and <200 nm in thickness) can hold the weight of a 156.3 g cell phone, highlighting the strong adhesive bond (FIG. 2(D)). In contrast, none of the heat conjugated polymers exhibited any adhesion. Overall, OTFTs with blends as the active layer possess good adhesive properties.

### Example 3

### Grazing-Incidence Wide-Angle X-Ray Scattering (GIWAXS)

GIWAXS was used to reveal how and/or if blending PCS with conjugated polymers affected crystallization of the conducting component. GIWAXS samples were cast on heavily doped p-type Si (100) wafers. Substrates were sonicated with acetone and isopropanol for 20 minutes each, dried with air, then subjected to UV-Ozone for 20 minutes. After UV-Ozone, surface treatment, spin coating thin-films, and annealing follows the same procedure as fabricating OTFTs. GIWAXS data was obtained on Beamline 7.3.3 at The Advanced Light Source, Lawrence Berkeley National Laboratory (λ=1.24 Å) using 10 keV X-rays and a Pilatus detector. GIWAXS measurements were taken at an angle of incidence of 0.14°, which is above the critical angle of all materials. The obtained 2D data were reduced to 1D profiles using Xi-Cam. Pandolfi et al., Xi-cam: a versatile interface for data visualization and analysis, J Synchrotron Radiation 25:1261-1270 (2018).

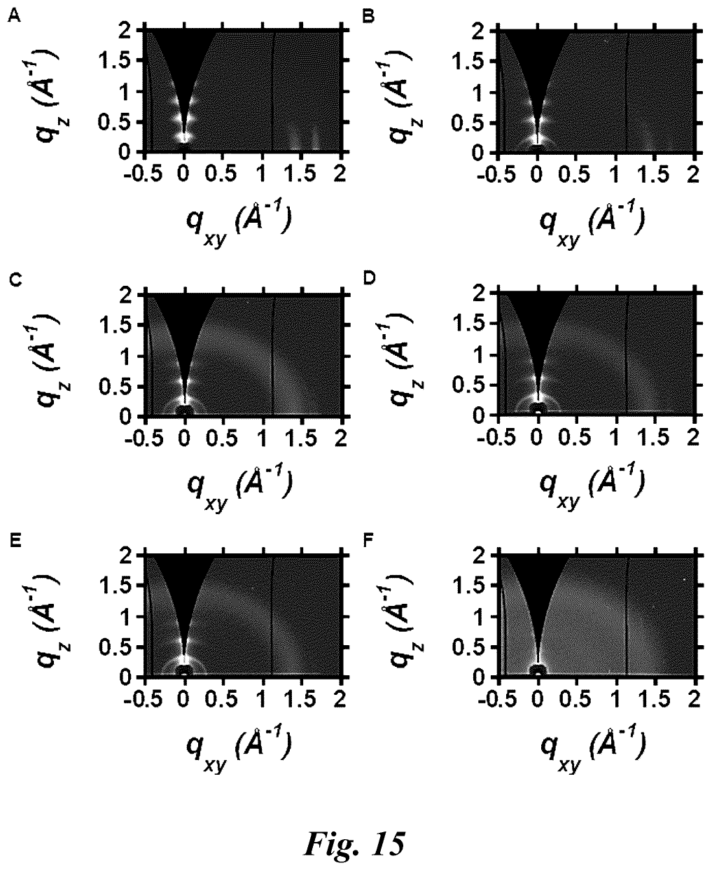

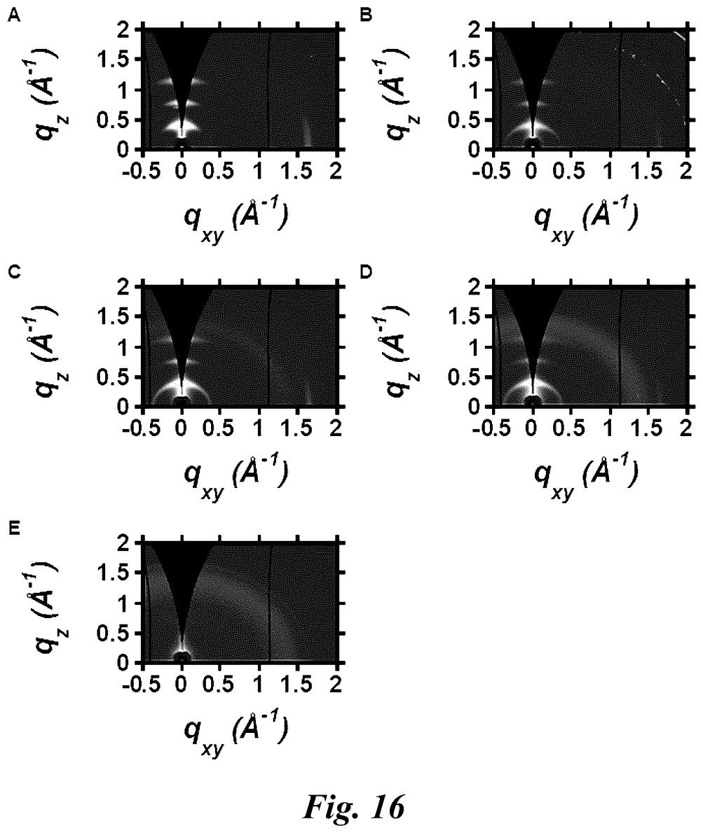

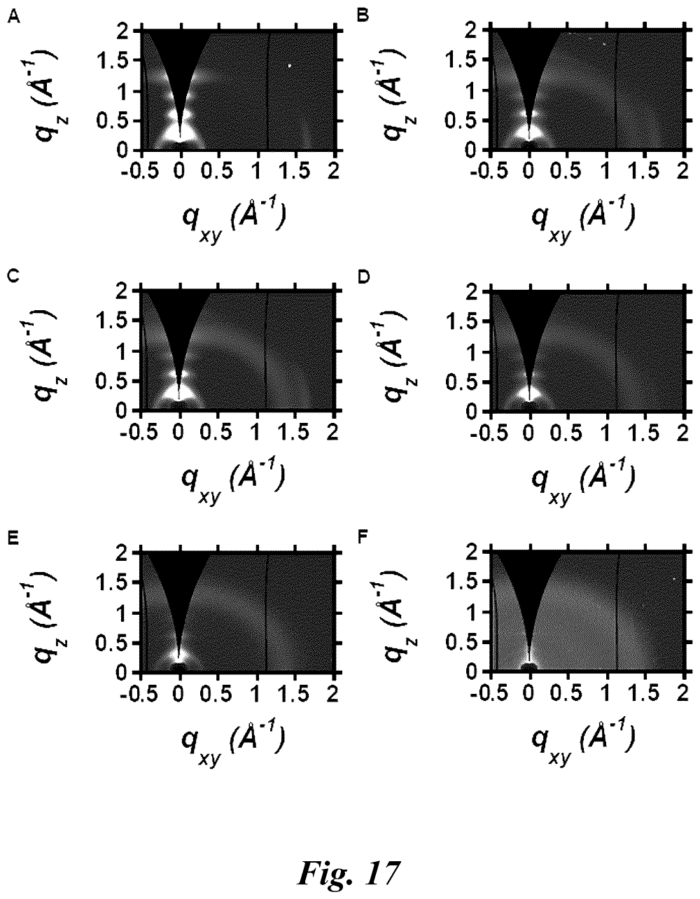

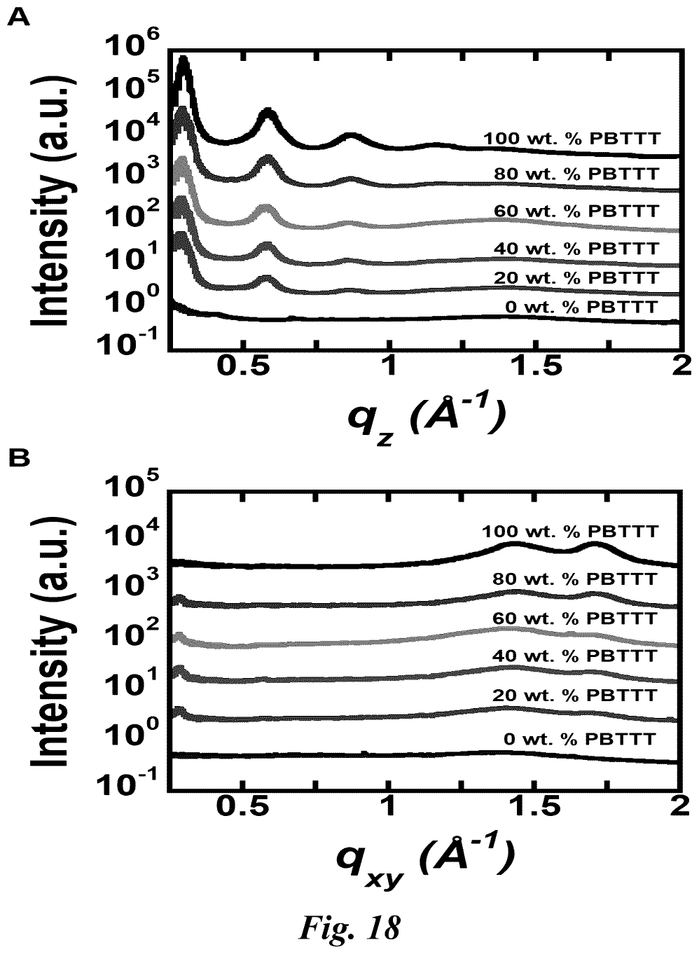

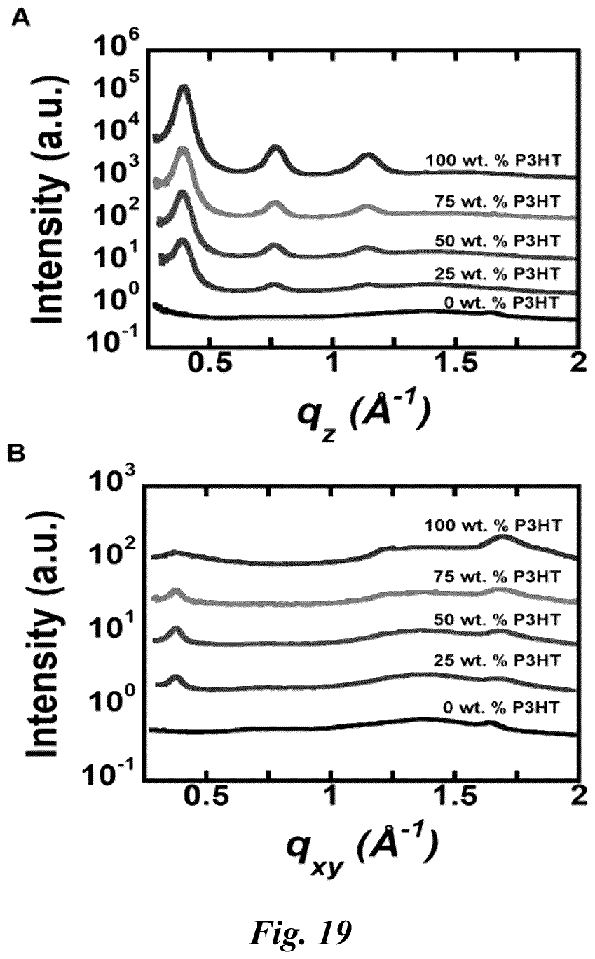

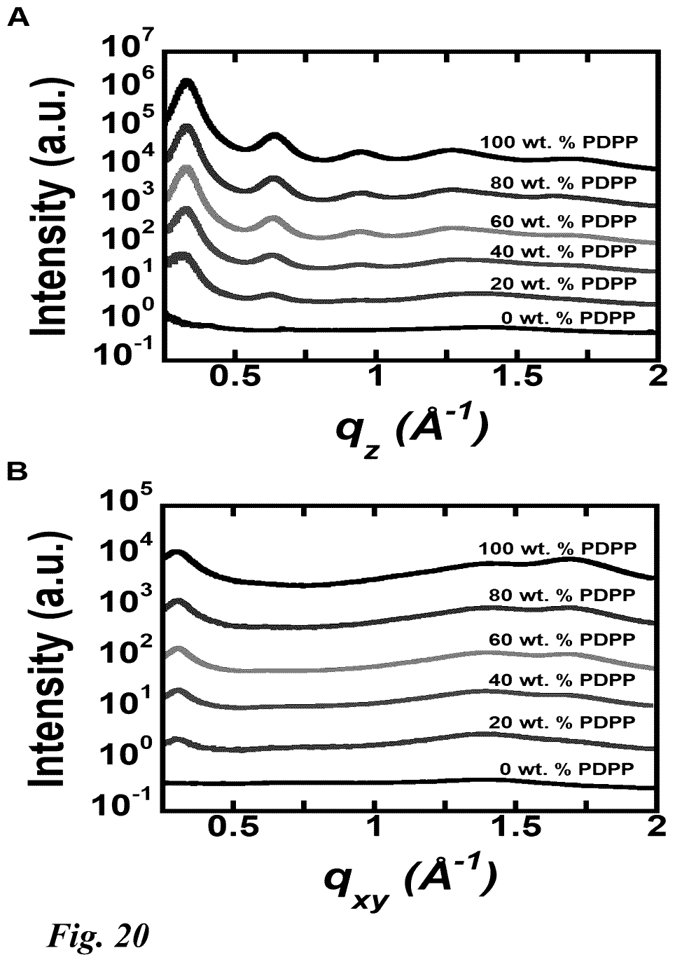

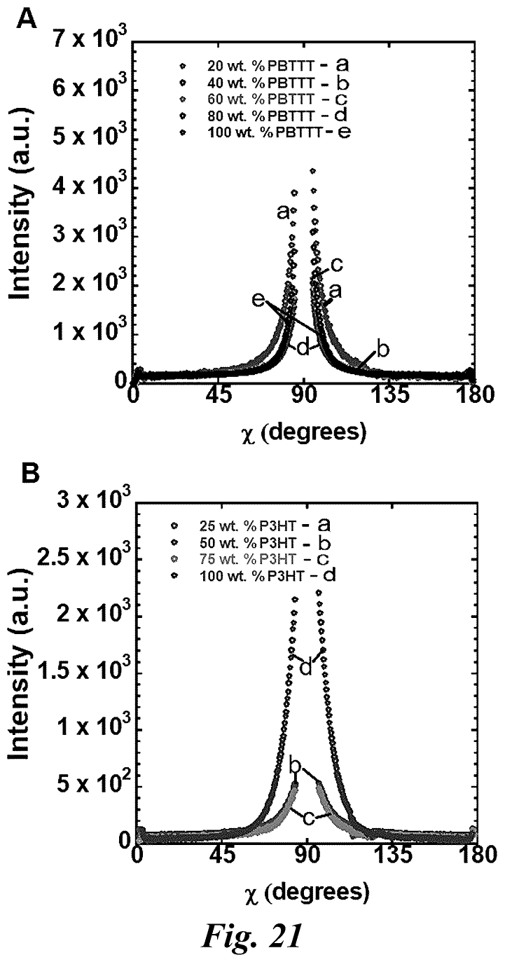

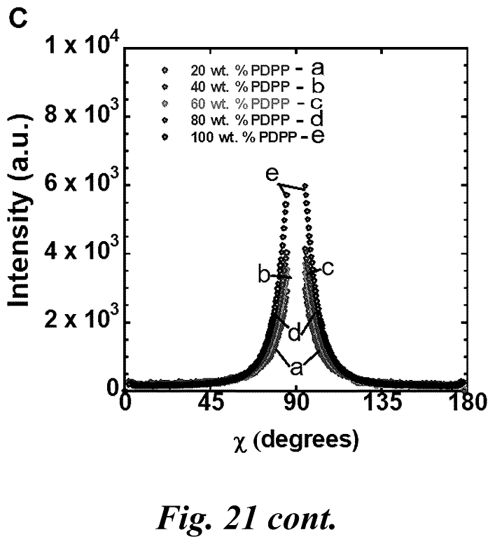

2D data for PBTTT/PCS blends, P3HT/PCS blends, and PDPP/PCS blends are shown in FIGS. 15-17, respectively. 1D scattering profiles are shown in FIG. 18 for PBTTT/PCS blends, FIG. 19 for P3HT/PCS blends, and FIG. 20 for PDPP/PCS blends. Intensities were normalized by exposure time, film thickness, and concentration of conjugated polymer. Azimuthally integrated (200) peak intensities in FIG. 21 were used to determine the relative crystallinity of the active layers and can be used to explain the trends observed in the device data. PBTTT/PCS blends (FIG. 21(A)) spectra shows that the intensity of the (200) peak did not significantly change as PCS was added. For the P3HT/PCS blends (FIG. 21(B)), the spectra shows that once PCS was added, the intensity of the (200) peak initially decreased then retained similar intensities for larger amounts of PCS. PDPP/PCS blends (FIG. 21(C)) GIWAXS data show a similar trend as the PBTTT/PCS blends in that the intensity of the (200) peak did not significantly change as PCS was added.

Given the trends in GIWAXS data, it was hypothesized that the up to 76.5% decrease in average mobility from 0.0742 cm² V⁻¹ s⁻¹ to 0.0174 cm² V⁻¹ s⁻¹ as PCS is added to PBTTT was due to dilution of the conjugated polymer. In the case of P3HT/PCS devices, the trend in the relative degree of crystallinity of the active layer did not follow device average mobility results, e.g., 50 and 75 wt. % P3HT devices statistically have the same average mobility as pure P3HT devices. Retainment of the mobility with the addition of PCS was similar to previous results.

Wang et al. has shown that the addition of regiorandom P3HT into a regioregular P3HT active layer does not lead to a decrease in charge mobility until regioregular P3HT content of the active layer is below 5.6 wt. %. Wang et al., Ultrathin body poly(3-hexylthiophene) transistors with improved short-channel performance, ACS Applied Materials Interfaces 5 (7): 2342-2346 (2013). This is despite a drop in crystallinity and is a result of vertical phase separation, where regioregular P3HT crystallizes at the dielectric interface to form a conducting channel. Likewise, P3HT/PCS blend devices exhibited constant average mobility as low as 50 wt. % P3HT before a 38.4% decrease in average mobility from 0.0683 cm² V⁻¹ s⁻¹ to 0.0421 cm² V⁻¹ s⁻¹ occurred at 25 wt. % P3HT, despite crystallinity decreasing when PCS was added. Accordingly, it was hypothesized that similar to the regioregular/regiorandom P3HT blend results, P3HT was present and preferentially crystallized at the semiconductor/dielectric layer interface even though PCS was present.

For the PDPP/PCS system, an up to 65.7% decrease in average mobility from 0.432 cm² V⁻¹ s⁻¹ to 0.148 cm² V⁻¹ s⁻¹ was observed when PCS was added. With the exception of the 60 wt. % PDPP and 80 wt. % PDPP blends, this was likely due to dilution effects. Lower average mobilities for those two systems could be a consequence of disruption of the conducting channel by the presence of PCS. The decrease in mobility in the PDPP/PCS devices could also be due to charge trapping by hydroxyl groups in PCS. Indeed, a less steep subthreshold slope from the transfer curves of PDPP/PCS blend devices was observed when compared to pristine PDPP devices, which could be a signature of induced traps. Nevertheless, the data did not provide evidence of induced traps in the P3HT and PBTTT blends (and indicated no changes in subthreshold slope).

There were subtle changes in the alkyl spacing and π-π stacking distances once PCS was added. For PBTTT/PCS blends, alkyl spacing distance increased from 21.5 Å up to 21.9 Å and π-π stacking distance increased from 3.69 Å up to 3.75 Å. Cochran et al., Molecular interactions and ordering in electrically doped polymers: blends of PBTTT and F₄TCNQ, Macromolecules 47 (19): 6836-6846 (2014); Kamatham et al., On the impact of linear siloxanated side chains on the molecular self-assembling and charge transport properties of conjugated polymers, Advanced Functional Materials 31 (6): 2007734 (2021). For P3HT/PCS blends, alkyl spacing distance increased from 16.4 Å up to 16.6 Å and π-π stacking distance increased from 3.72 Å up to 3.75 Å. Chu et al., Flexible ofets: synergistic effect of regioregular and regiorandom poly(3-hexylthiophene) blends for high performance flexible organic field effect transistors, Advanced Electronic Materials 2 (2): 1500384 (2016); Zhai et al., Surface etching of polymeric semiconductor films improves environmental stability of transistors, Chemistry Materials 33 (7): 2673-2682 (2021).

For PDPP/PCS blends, alkyl spacing distance increased from 19.6 Å up to 20.0 Å and π-π stacking distance increased from 3.72 Å up to 3.77 Å. Wu et al., Achieving high performance stretchable conjugated polymers via donor structure engineering, Macromolecular Rapid Communications 44 (17): 2300169 (2023); Wu et al., Rapid self-assembly process at air/water confined interface for highly aligned crystalline polymeric semiconductor films, Advanced Electronic Materials 9 (6): 2300029 (2023).

In the PBTTT/PCS and P3HT/PCS systems, the addition of PCS caused some of the conjugated polymer chains to align in the face on orientation. For PBTTT/PCS blends, in-plane alkyl spacing distance ranged from 22.0 Å to 22.8 Å, which is close to the out-of-plane alkyl spacing distance. For P3HT/PCS blends, in-plane alkyl spacing distance ranged from 16.7 Å to 17.1 Å.

An increase in alkyl spacing distance, π-π stacking distance, and the presence of in-plane alkyl spacing all are additional contributors to the decrease in field-effect charge carrier mobility as PCS was added.

### Example 4

### Adhesion Assessments

Various characterization techniques were used to explain the decrease in mobility and understand thin-film morphology of the multifunctional active layer of the OTFTs hereof. More specifically, AFM, time-of-flight secondary ion mass spectrometry (ToF-SIMS), and angle resolved X-ray photoelectron spectroscopy (AR-XPS) were used for thin-film morphology characterization and to further assess adhesion. The results supported that the thin blend films hereof can achieve good adhesion regardless of the composition of the active layer.

AFM samples were prepared and tested as described in Example 2.

ToF-SIMS samples were prepared similarly to how the OTFTs were fabricated, except that bare Si/SiO₂ were used. ToF-SIMS depth profiling was performed on a Physical Electronics NanoTOF II instrument. Samples were mounted behind a 5 mm aperture mask. The spectroscopy beam is 30 keV Bi₃⁺ and the gas cluster ion beam (GCIB) is 5 keV Ar⁺₅₀₀₀. The spectroscopy beam raster size was 100 microns×100 microns with a beam strength of about 1.8 nA, 100 microns column aperture. GCIB raster size was 600 microns×600 microns with a beam strength of 4.2 nA. The GCIB did a 5 second etch per cycle for 30 cycles. Mass resolution was about 3000 with contrast diaphragm out. Ratemeter was about 25 kCPS during acquisition. For spectroscopy acquisition, 2 frames per cycle, 2*10¹⁰ dose, and 256×256 image resolution were used with an end mass of 1850. Electron neutralizer was used for negative ion spectral acquisition. Electron and ion neutralization were used during GCIB sputtering.

AR-XPS samples were prepared similarly to how GIWAXS and AFM samples were prepared. AR-XPS experiments were performed using a Physical Electronics VersaProbe II instrument equipped with a monochromatic Al kα X-ray source (hv=1,486.7 eV) and a concentric hemispherical analyzer. Charge neutralization was performed using both low energy electrons (<5 eV) and argon ions. The binding energy axis was calibrated using sputter cleaned Cu (Cu 2p_{3/2}=932.62 eV, Cu 3p_{3/2}=75.1 eV) and Au foils (Au 4f_{7/2}=83.96 eV). Peaks were charge referenced to CHx band in the carbon 1 second spectra at 284.8 eV. Measurements were made at takeoff angles of 30° and 80° with respect to the sample surface plane. This resulted in a typical sampling depth of 3-4 nm and 6-8 nm, respectively (95% of the signal originated from this depth or shallower). Quantification was performed using instrumental relative sensitivity factors (RSFs) that account for the X-ray cross section and inelastic mean free path of the electrons.

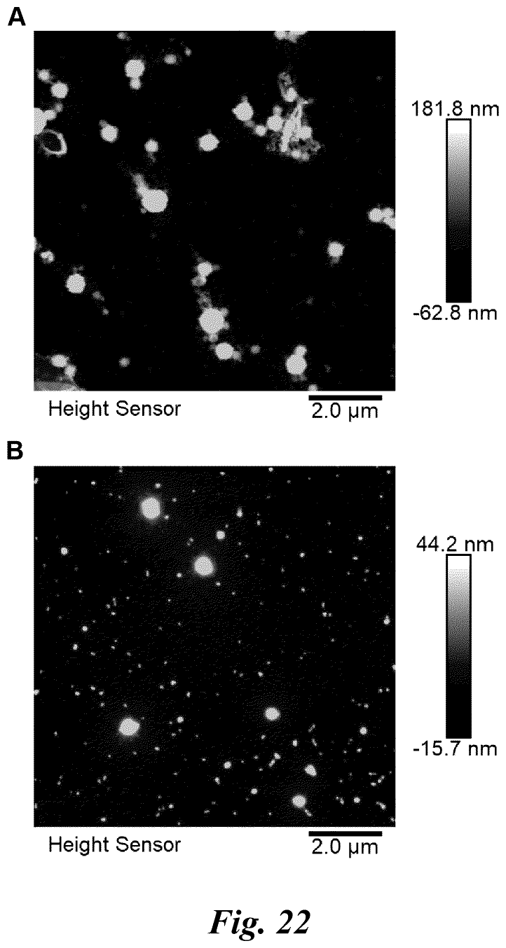

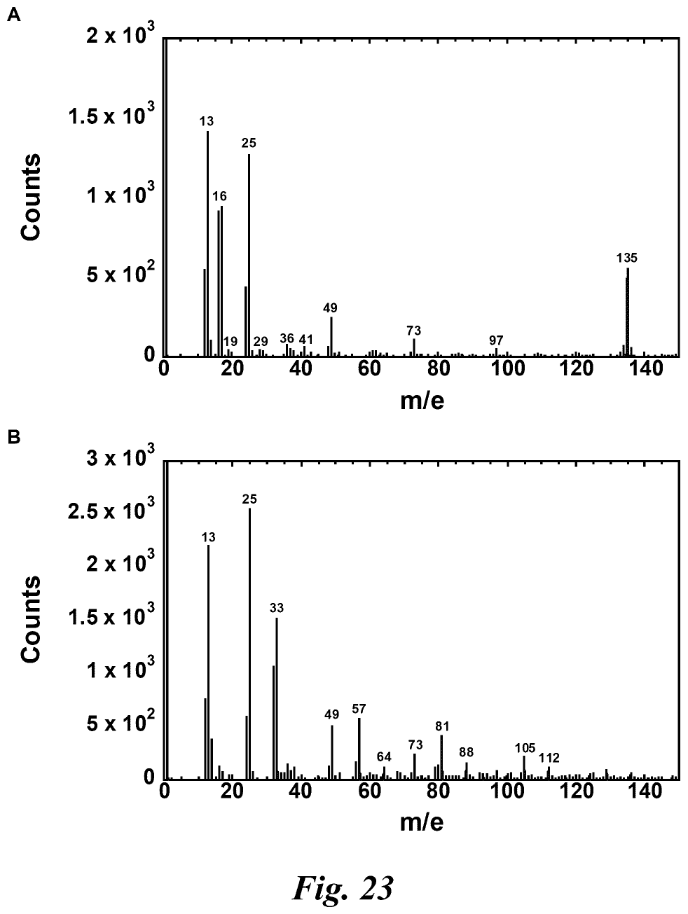

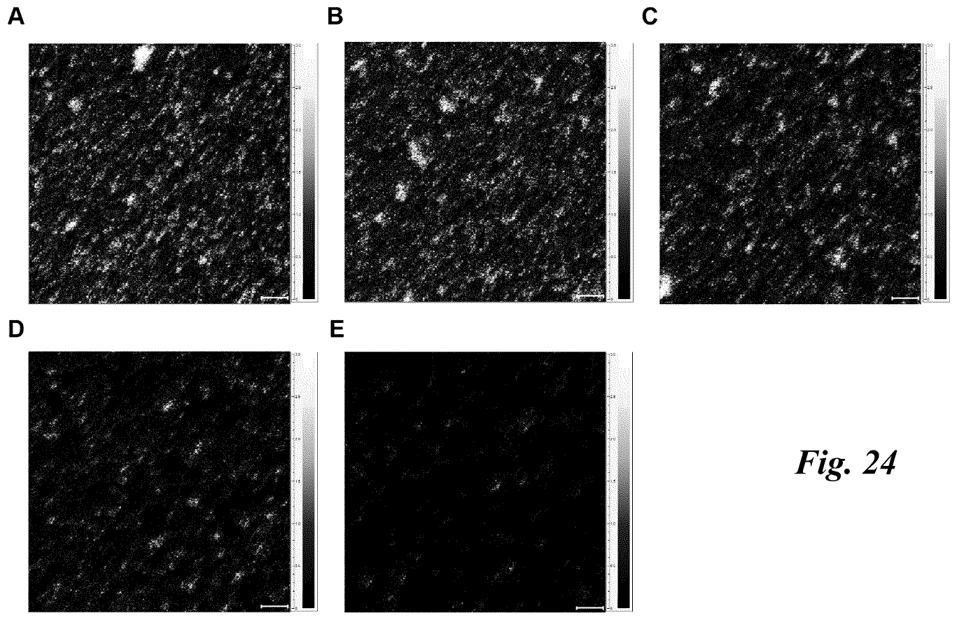

The AFM images of pristine PCS films show PCS on the surface as spheres or nodules (FIG. 22(A)). Negative ion spectra of pristine PBTTT and PCS films from ToF-SIMS (FIG. 23) show that m/e of 135 is a good marker for PCS. The obtained images at m/e of 135 (FIG. 24) show that PCS appears as granular dots, thus confirming the dots that appear on the AFM images are PCS. These spherical PCS particles could act as adhesion sites for bonding to the film surface.

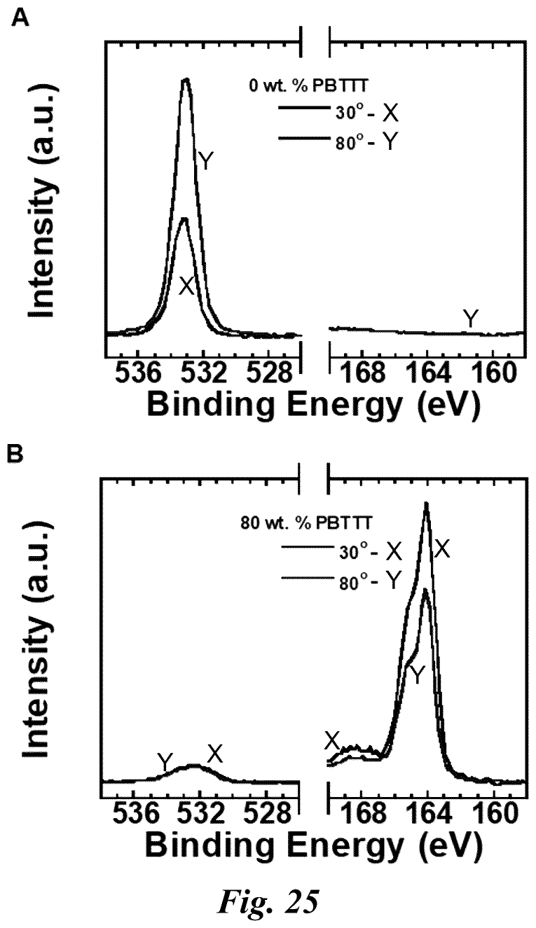

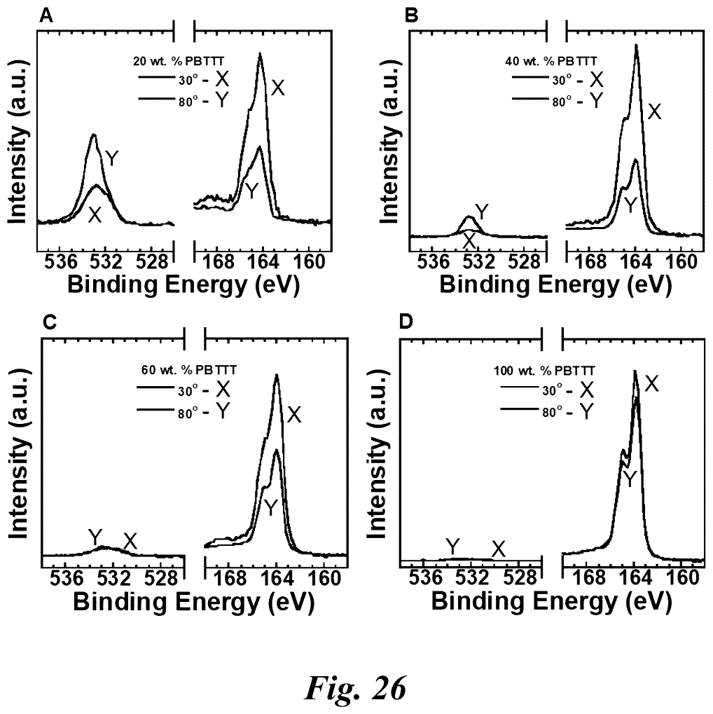

For PBTTT/PCS blend films, the RMS roughness decreased from 37.3 nm to 5.67 nm once PBTTT was added (FIG. 22(B)). The order of magnitude decrease in RMS roughness could cause stronger adhesion between two films. Intensity of the S 2p signal of PBTTT at 30° (surface) was stronger than at 80° (bulk) in the AR-XPS spectra. As such, AR-XPS spectra of PBTTT/PCS films (FIGS. 25-26) suggests that PBTTT is rich at the surface of the film while PCS is rich in the bulk.

In addition, the intensity of the O Is signal of PCS either remained the same or increased in strength when the takeoff angle changed from 30° (surface) to 80° (bulk). Although the S 2p signal was stronger on the surface, there was still sufficient PCS present on the surface to bond two films together.

The ability to bond all compositions of P3HT/PCS films can be explained using AFM and AR-XPS. 75 wt. % P3HT had the lowest RMS roughness as compared to the other two blend compositions; 2.90 nm compared to as high as 44.3 nm (FIGS. 13(B)-(E) and Table 1).

TABLE 1
RMS roughness values of P3HT/PCS blend films
at different weight percent of P3HT.

| Wt. % P3HT | RMS Roughness (nm) |
|---|---|
| 0 | 42.2 |
| 25 | 44.3 |
| 50 | 25.0 |
| 75 | 2.90 |

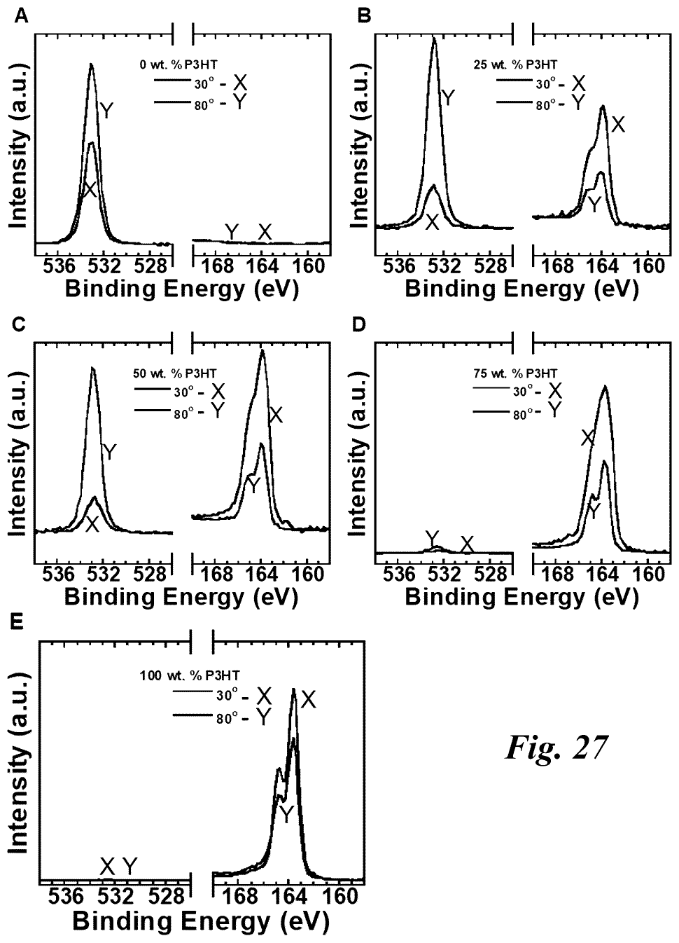

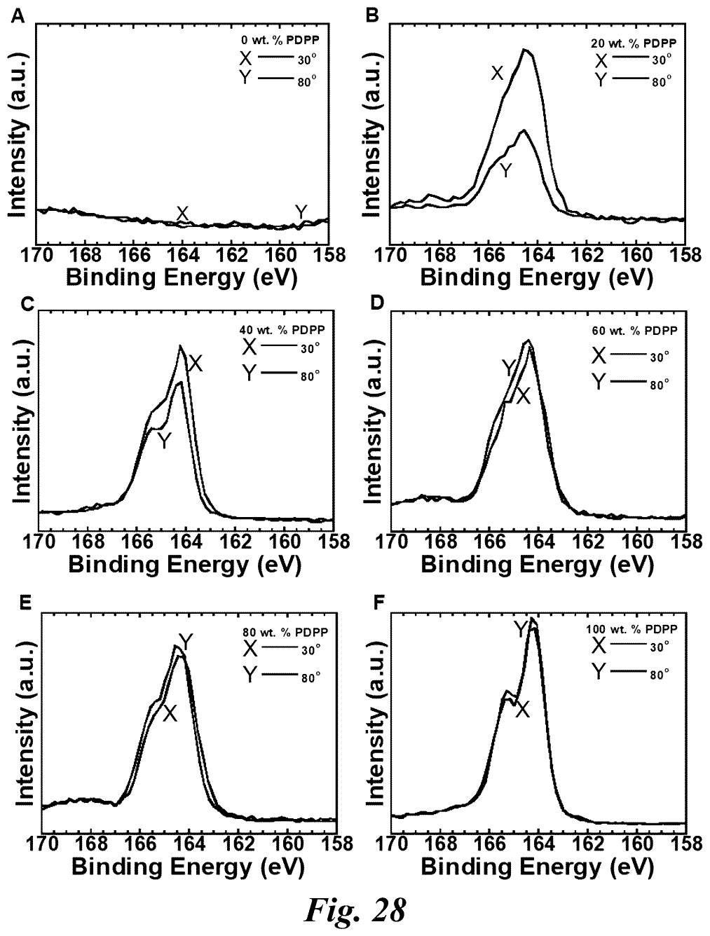

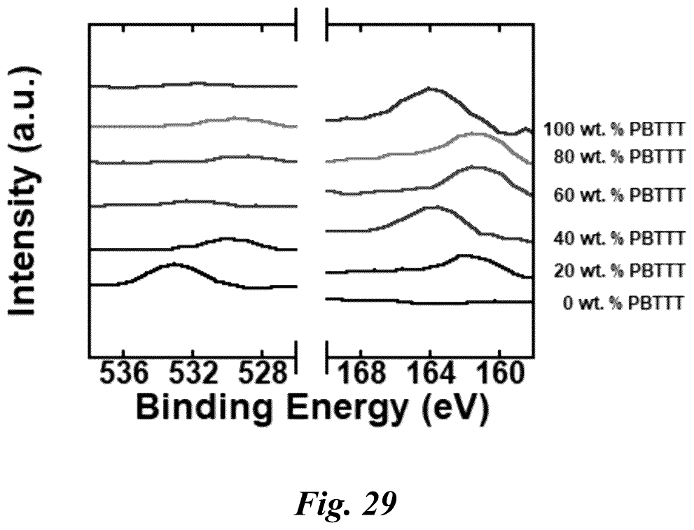

AR-XPS showed the strongest O 1s signal at 25 wt. % P3HT when takeoff angle was 30° (FIG. 27). This suggests that PCS is rich in the surface at this composition compared to the other two blend compositions at 30° takeoff angle. The ability to bond all compositions of PDPP/PCS films can be explained in a similar manner as P3HT/PCS films. PCS is present on the surface of the films even though the surface is rich in PDPP (S 2p peak decreases as takeoff angles changes from 30° to) 80° (FIG. 28). XPS data from blends of various compositions also confirmed the enrichment of conjugated polymer at the surface of PBTTT/PCS films (FIG. 29).

RMS roughness slightly increased as the amount of PDPP increased, from 43.8 nm at 20 wt. % PDPP to 47.4 nm at 60 wt. % PDPP. At 80 wt. % PDPP, due to the surface being significantly rich in PDPP, the RMS roughness decreased to 29.3 nm (FIGS. 14(B)-(E) and Table 2).

TABLE 2
RMS roughness values of PDPP/PCS blend films
at different weight percent of PDPP.

| Wt. % PDPP | RMS Roughness (nm) |
|---|---|
| 0 | 37.3 |
| 20 | 43.8 |
| 60 | 47.4 |
| 80 | 29.3 |

These characterization results support that a balance between surface roughness and the amount of PCS at the bonding interface plays an important role in the adhesion process, and that blending can be used to optimize thin-film adhesion by smoothening out the surface of the films and obtaining an adequate amount of PCS on the surface.

Further, different compositions of conjugated polymer and adhesive polymer in thin-films can lead to only a modest decrease in field-effect charge carrier mobilities, with the largest decrease observed being only roughly half an order of magnitude (20 to 100% conjugated polymer). For example, a decrease in mobility can be attributed to dilution effects for PBTTT/PCS and PDPP/PCS blends, and a decrease in crystallinity for the P3 HT/PCS blends (as confirmed using GIWAXS). AFM images confirmed a decrease in RMS roughness as a conjugated polymer is added to the active layer. The presence of PCS on the surface of the film of a conjugated polymer added to the active layer was confirmed from AR-XPS.

1. A polymer comprising a poly(vinyl catechol-styrene) (PCS) and at least one conjugated polymer, the conjugated polymer comprising at least one poly(alkyl-thiophene) derivative or at least one high-performance donor-acceptor polymer.

2. The polymer of claim 1, wherein the poly(alkyl-thiophene) derivative comprises poly(3-hexylthiophene-2,5-diyl) (P3HT) or poly[2,5-bis(3-tetradecylthiophen-2-yl) thieno[3,2-b]thiophene] (PBTTT).

3. The polymer of claim 1, wherein the high-performance donor-acceptor polymer comprises poly[2,5-(2-octyldodecyl)-3,6-diketopyrrolopyrrole-alt-5,5-(2,5-di(thien-2-yl) thieno[3,2-b]thiophene)] (PDPP).

4. The polymer of claim 1, wherein the poly(alkyl-thiophene) derivative comprises about 20 weight percentage (wt. %) to about 99 wt. % of the polymer.

5. The polymer of claim 1, wherein the poly(alkyl-thiophene) derivative comprises P3HT and is present in at or about 10-25 wt. % of the polymer.

6. The polymer of claim 1, wherein the high-performance donor-acceptor polymer comprises PDPP and is present in at or about 15-65 wt. % of the polymer.

7. The polymer of claim 1, wherein the high-performance donor-acceptor polymer comprises PDPP and is present in at or about 60 wt. % of the polymer.

8. The polymer of claim 1, wherein the polymer exhibits both semiconductive and adhesive properties.

9. The polymer of claim 1, wherein the polymer exhibits an adhesive strength of about 0.05 MPa to about 4.30 MPa.

10. An organic thin-film transistor (OTFT) comprising:
a semiconductor active layer comprising a polymer blend comprising a poly(vinyl catechol-styrene) (PCS) and at least one conjugated polymer, the conjugated polymer comprising at least one poly(alkyl-thiophene) derivative or at least one high-performance donor-acceptor polymer;
at least two electrodes in conductive communication with the semiconductive active layer;
an insulating layer; and
a lowermost substrate comprising a gate;
wherein the semiconductive active layer is cast over the at least two electrodes, the insulating layer, and the substrate.

11. The OTFT of claim 10, wherein the substrate comprises heavily doped p-type silicon.

12. The OTFT of claim 10, wherein the insulating layer is a dielectric layer.

13. The OTFT of claim 10, wherein the insulating layer comprises 300 nm silicon dioxide.

14. The OTFT of claim 13, wherein the silicon dioxide is thermally grown.

15. The OTFT of claim 10, wherein at least one of the electrodes is a drain and at least one of the electrodes is a source.

16. The OTFT of claim 10, wherein the active layer exhibits an adhesive strength of about 0.05 MPa to about 4.30 MPa.

17. The OTFT of claim 10, comprising a bottom gate, bottom contact configuration.

18. The OTFT of claim 10, wherein at least two of the at least two electrodes are arranged separately from each other.

19. The OTFT of claim 15, wherein both the electron source and the electron drain comprise gold.

20. A method of preparing an organic thin-film transistor (OTFT) comprising:
evaporating and patterning two or more electrodes onto a substrate;
depositing a polymer blend in solution onto an insulating layer positioned over the substrate or onto the substrate, the polymer blend comprising a poly(vinyl catechol-styrene) (PCS) and at least one conjugated polymer, the conjugated polymer comprising at least one poly(alkyl-thiophene) derivative or at least one high-performance donor-acceptor polymer; and
processing the deposited polymer blend solution;
wherein the resulting OTFT comprises a semiconductor active layer comprising the polymer blend, the two or more electrodes are in conductive communication with the semiconductive active layer, and at least a portion of the substrate comprises a gate.
